(19) United States
(12) Patent Application Publication
(10) Pub. No.: US 2025/0221227 A1
(43) Pub. Date: Jul. 3, 2025

(54) DISPLAY DEVICE, METHOD OF MANUFACTURING THE SAME, AND ELECTRONIC DEVICE INCLUDING THE SAME

(71) Applicant: SAMSUNG DISPLAY CO., LTD., YONGIN-Si (KR)

(72) Inventors: MINSEOK KIM, Yongin-si (KR); SONGYI KIM, Yongin-si (KR); SUJIN KIM, Yongin-si (KR); DONG GYU BAECK, Yongin-si (KR); YONGSEOK CHOI, Yongin-si (KR)

(21) Appl. No.: 18/985,508

(22) Filed: Dec. 18, 2024

(30) Foreign Application Priority Data
Jan. 3, 2024 (KR) 10-2024-0001177

(51) Int. Cl. H10K 59/38; H10K 59/12; H10K 59/122; H10K 59/80; H10K 102/00

(52) U.S. Cl. CPC H10K 59/38; H10K 59/1201; H10K 59/122; H10K 59/8792; H10K 2102/331

(57) ABSTRACT

A display device includes: a substrate that includes first to third light emitting areas and a light blocking area that surrounds the first to third light emitting areas; a light emitting layer that includes first to third light emitting layers disposed in the first to third light emitting areas, respectively; and a color conversion layer that includes a first bank disposed in the first light emitting area on the light emitting layer, overlaps an edge of the first light emitting layer, and includes a first opening that exposes a central portion of the first light emitting layer, a second bank disposed in the light blocking area on the light emitting layer, contacts a side surface of the first bank, and includes a material different from the first bank, and a first color conversion pattern disposed inside the first opening.

### CROSS-REFERENCE TO RELATED APPLICATION

This application claims priority under 35 U.S.C. § 119 from Korean Patent Application No. 10-2024-0001177, filed on Jan. 3, 2024 in the Korean Intellectual Property Office, the contents of which are herein incorporated by reference in their entirety.

### TECHNICAL FIELD

Embodiments of the present disclosure are generally directed to a display device. More particularly, embodiments of the present disclosure are directed to a display device, a method of manufacturing the same, and an electronic device including the same.

### DISCUSSION OF THE RELATED ART

With the development of information technology, the importance of a display device, which is a connection medium between a user and information, has increased. For example, the use of display devices, such as liquid crystal display (LCD) devices, organic light emitting display (OLED) devices, plasma display panel (PDP) devices, quantum dot display devices, etc., is increasing.

To reduce light loss in a display device and to display colors with high efficiency, a color conversion layer and a display device including the same have been proposed. Recently, much research has been conducted to increase the light efficiency of a display device.

### SUMMARY

Embodiments provide a display device with increased light efficiency and reduced color mixing phenomenon.

Embodiments provide a method of manufacturing the display device.

Embodiments provide an electronic device including the display device.

A display device according to an embodiment of the present disclosure includes a substrate that includes first to third light emitting areas and a light blocking area that surrounds the first to third light emitting areas, a light emitting layer that includes first to third light emitting layers disposed on the substrate in the first to third light emitting areas, respectively, and a color conversion layer. The color conversion layer includes a first bank disposed in the first light emitting area on the light emitting layer, overlaps an edge of the first light emitting layer in a plan view, and includes a first opening that exposes a central portion of the first light emitting layer, a second bank disposed in the light blocking area on the light emitting layer, contacts a side surface of the first bank, and includes a material different from the first bank, and a first color conversion pattern disposed inside the first opening in the first light emitting area.

In an embodiment, the first bank includes a scattering particle, and the second bank includes carbon black.

In an embodiment, the color conversion layer further includes a first transmission pattern disposed in the second light emitting area on the light emitting layer and that is surrounded by the second bank, and a second transmission pattern disposed in the third light emitting area on the light emitting layer and that is surrounded by the second bank.

In an embodiment, the first conversion pattern converts light emitted from the light emitting layer into light of a first color. Each of the first transmission pattern and the second transmission pattern transmit the light emitted from the light emitting layer.

In an embodiment, the first color is red, and each of the first to third light emitting layers emits green light and blue light.

In an embodiment, the first bank includes a same material as the first transmission pattern and the second transmission pattern.

In an embodiment, the first bank is further disposed in the second light emitting area on the light emitting layer, overlaps an edge of the second light emitting layer in a plan view, and includes a second opening that exposes a central portion of the second light emitting layer. The color conversion layer further includes a second color conversion pattern disposed inside the second opening in the second light emitting area, and a transmission pattern disposed in the third light emitting area on the light emitting layer and that is surrounded by the second bank.

In an embodiment, the first color conversion pattern converts light emitted from the light emitting layer into light of a first color. The second color conversion pattern coverts the light emitted from the light emitting layer into light of a second color. The transmission pattern transmits the light emitted from the light emitting layer.

In an embodiment, the first color is red, the second color is green, and each of the first to third light emitting layers emits only blue light, or emits green light and blue light.

In an embodiment, the second bank includes a liquid-repellent material.

In an embodiment, the display device further includes a color filter layer disposed on the color conversion layer and that includes first to third color filters that overlap the first to third light emitting areas, respectively.

A method of manufacturing a display device according to an embodiment of the present disclosure includes forming a color filter layer on a first substrate that includes first to third light emitting areas and a light blocking area that surrounds the first to third light emitting areas, where the color filter layer includes first to third color filters that overlap the first to third light emitting areas, respectively, forming a preliminary layer on the color filter layer, patterning the preliminary layer and forming a first bank that overlaps an edge of the first color filter in a plan view and includes a first opening that exposes a central portion of the first color filter in the first light emitting area, forming a second bank that overlaps the light blocking area, contacts a side surface of the first bank, and includes a material different from the first bank, forming a first color conversion pattern that overlaps the first light emitting area and is disposed inside the first opening, and forming a light emitting layer on a second substrate and bonding the first substrate and the second substrate such that the light emitting layer overlaps each of the first to third light emitting areas.

In an embodiment, the first bank includes a scattering particle, and the second bank includes carbon black.

In an embodiment, the method further includes patterning the preliminary layer and forming a first transmission pattern that overlaps the second color filter in the second light emitting area in a plan view and a second transmission pattern that overlaps the third color filter in the third light emitting area in a plan view. The first transmission pattern and the second transmission pattern are simultaneously formed with the first bank.

In an embodiment, the method further includes patterning the preliminary layer and forming a transmission pattern that overlaps the third color filter in the third light emitting area in a plan view. The first bank further overlaps an edge of the second color filter in a plan view and further includes a second opening that exposes a central portion of the second color filter in the second light emitting area. The transmission pattern is simultaneously formed with the first bank.

In an embodiment, the method further includes forming a second color conversion pattern that overlaps the second light emitting area and is disposed inside the second opening.

A method of manufacturing a display device according to an embodiment of the present disclosure includes forming a light emitting layer on a substrate that includes first to third light emitting areas and a light blocking area that surrounds the first to third light emitting areas, where the light emitting layer include first to third light emitting layers that overlap the first to third light emitting areas, respectively, forming a preliminary layer on the light emitting layer, patterning the preliminary layer and forming a first bank that overlaps an edge of the first light emitting layer in a plan view and includes a first opening that exposes a central portion of the first light emitting layer in the first light emitting area, forming a second bank that overlaps the light blocking area, contacts a side surface of the first bank, and includes a material different from the first bank, and forming a first color conversion pattern that overlaps the first light emitting area and is disposed inside the first opening.

In an embodiment, the method further includes patterning the preliminary layer and forming a first transmission pattern that overlaps the second light emitting layer in the second light emitting area in a plan view and a second transmission pattern that overlaps the third light emitting layer in the third light emitting area in a plan view. The first transmission pattern and the second transmission pattern simultaneously formed with the first bank.

In an embodiment, the method further includes patterning the preliminary layer and forming a transmission pattern that overlaps the third light emitting layer in the third light emitting area in a plan view. The first bank further overlaps an edge of the second light emitting layer in a plan view and further includes a second opening that exposes a central portion of the second light emitting layer in the second light emitting area. The transmission pattern is simultaneously formed with the first bank.

In an embodiment, the method further includes forming a second color conversion pattern that overlaps the second light emitting area and is disposed inside the second opening.

An electronic device according to an embodiment of the present disclosure includes a display device and a power supply configured to provide power to the display device. The display device includes a substrate that includes first to third light emitting areas and a light blocking area that surrounds the first to third light emitting areas, a light emitting layer that includes first to third light emitting layers disposed on the substrate in the first to third light emitting areas, respectively, and a color conversion layer. The color conversion layer includes a first bank disposed in the first light emitting area on the light emitting layer, overlaps an edge of the first light emitting layer in a plan view, and includes a first opening that exposes a central portion of the first light emitting layer, a second bank disposed in the light blocking area on the light emitting layer, contacts a side surface of the first bank, and includes a material different from the first bank, and a first color conversion pattern disposed inside the first opening in the first light emitting area.

A display device according to an embodiment of the present disclosure includes: a substrate that includes first to third light emitting areas and a light blocking area that surrounds the first to third light emitting areas; a light emitting layer that includes first to third light emitting layers respectively disposed in the first to third light emitting areas on the substrate; a first bank disposed in the first light emitting area on the light emitting layer, overlaps an edge of the first light emitting layer, and includes a first opening that exposes a central portion of the first light emitting layer; a second bank disposed in the light blocking area on the light emitting layer, contacts a side surface of the first bank, and includes a material different from the first bank; and a first color conversion pattern disposed inside the first opening in the first light emitting area. The first bank includes scattering particles, and the second bank includes carbon black.

Since the first bank includes scattering particles, the first bank reflects or scatters light incident from the light emitting layer. In addition, the first bank reflects or scatters light incident from the first color conversion pattern. The light reflected or scattered from the first bank is reused in the first color conversion pattern, and thus light efficiency increases in the first light emitting area.

Since the second bank includes carbon black, as compared to a light blocking bank formed by mixing black pigment with other pigments, the second bank effectively blocks or absorbs light incident from adjacent light emitting layers. Accordingly, a color mixing phenomenon that can occur between adjacent sub-pixels is reduced.

### BRIEF DESCRIPTION OF THE DRAWINGS

FIG. 1 is a plan view of a display device according to an embodiment of the present disclosure.

FIG. 2 is a cross-sectional view taken along line I-I′ of FIG. 1.

FIG. 3 is a cross-sectional view of a color conversion layer in the display device of FIG. 2.

FIGS. 4 and 5 illustrate light intensity as a function of a wavelength of light emitted from the display device of FIG. 2.

FIG. 6 is a cross-sectional view of a display device according to an embodiment of the present disclosure.

FIG. 7 is a cross-sectional view of a color conversion layer in the display device of FIG. 6.

FIG. 8 is a cross-sectional view of a display device according to an embodiment of the present disclosure.

FIG. 9 is a cross-sectional view of a display device according to an embodiment of the present disclosure.

FIG. 10 is a flowchart of a method of manufacturing a display device according to an embodiment of FIG. 1.

FIGS. 11, 12, 13, 14, 15, 16, 17, and 18 illustrate a method of manufacturing a display device of FIG. 10.

FIG. 19 is a flowchart of a method of manufacturing a display device according to an embodiment of FIG. 6.

FIGS. 20, 21, 22, 23, 24, and 25 illustrate a method of manufacturing a display device of FIG. 19.

FIG. 26 is a block diagram of an electronic device according to an embodiment of the present disclosure.

FIG. 27 illustrates an example in which the electronic device of FIG. 26 is implemented as a smart phone.

FIG. 28 illustrates an example in which the electronic device of FIG. 26 is implemented as a computer monitor.

### DETAILED DESCRIPTION

Hereinafter, embodiments of the present disclosure will be described in detail with reference to the accompanying drawings. The same reference numerals may be used for the same components in the drawings, and redundant descriptions of the same components may be omitted.

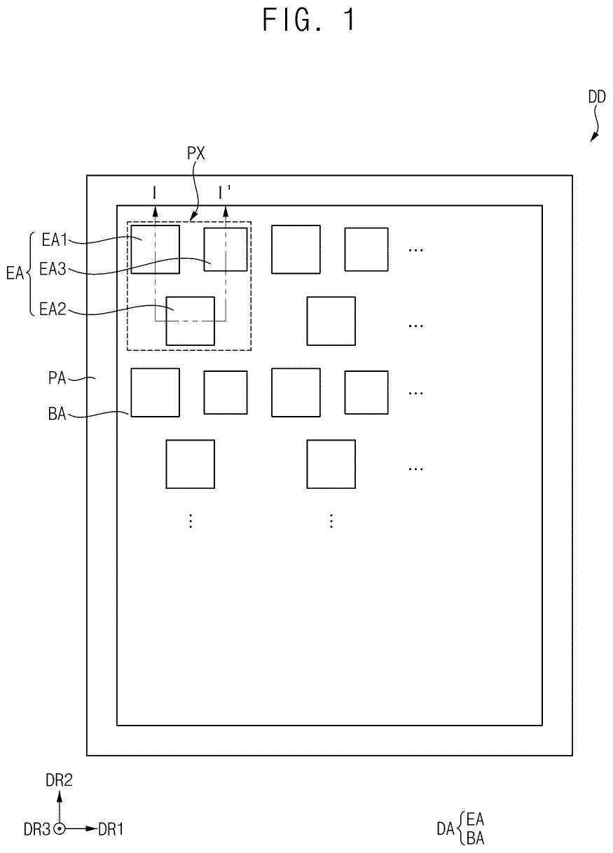

FIG. 1 is a plan view of a display device according to an embodiment of the present disclosure.

In this specification, a plane may be defined by a first direction DR1 and a second direction DR2 that intersects the first direction DR1. For example, the first direction DR1 and the second direction DR2 may be perpendicular to each other. A direction normal to the plane, such as a thickness direction of a display device DD, may be a third direction DR3. In other words, the third direction DR3 may be perpendicular to each of the first direction DR1 and the second direction DR2.

Referring to FIG. 1, the display device DD according to an embodiment of the present disclosure includes a display area DA and a peripheral area PA.

The display area DA is where an image is displayed by generating light or adjusting the transmittance of light provided from an external light source. A plurality of pixels PX are disposed in the display area DA. Each of the pixels PX generates light according to a driving signal. The pixels PX are repeatedly disposed along a row direction and a column direction. For example, the pixels PX are repeatedly disposed along the first direction DR1 and the second direction DR2. Each of the pixels PX includes a first sub-pixel, a second sub-pixel, and a third sub-pixel.

The display area DA includes a plurality of light emitting areas EA and a light blocking area BA. Each of the light emitting areas EA includes a first light emitting area EA1, a second light emitting area EA2, and a third light emitting area EA3. For example, the first sub-pixel overlaps the first light emitting area EA1, the second sub-pixel overlaps the second light emitting area EA2, and the third sub-pixel overlaps the third light emitting area EA3.

Each of the first to third light emitting areas EA1, EA2, and EA3 is where light is emitted from the light emitting element out from the display device DD. For example, the first light emitting area EA1 emits first light, the second light emitting area EA2 emits second light, and the third light emitting area EA3 emits third light. In an embodiment, the first light is red light, the second light is green light, and the third light is blue light. However, embodiments of the present disclosure are not necessarily limited thereto. For example, in some embodiments, the first to third light emitting areas EA1, EA2, and EA3 are combined to emit yellow light, cyan light, and magenta light.

In a plan view, each of the first to third light emitting areas EA1, EA2, and EA3 is repeatedly arranged along the first direction DR1 and the second direction DR2. For example, the first light emitting area EA1 and the third light emitting area EA3 are alternately arranged along the first direction DR1 in an odd-numbered row, such as a first row, of the display area DA. In addition, the second light emitting area EA2 is repeatedly arranged along the first direction DR1 in an even-numbered row, such as a second row, adjacent to the odd-numbered row of the display area DA.

Areas of the first to third light emitting areas EA1, EA2, and EA3 differ from each other. In an embodiment, the area of the first light emitting area EA1, which emits red light, is greater than an area of each of the second light emitting area EA2, which emits green light, and the third light emitting area EA3, which emits blue light. For example, the area of the second light emitting area EA2 is greater than the area of the third light emitting area EA3. However, embodiments of the present disclosure are not necessarily limited thereto. For example, in some embodiments, the area of the second light emitting area EA2 is greater than the area of the each of first light emitting area EA1 and the third light emitting area EA3. For example, the area of the first light emitting area EA1 is greater than the area of the third light emitting area EA3.

Each of the first to third light emitting areas EA1, EA2, and EA3 has one of the following planar shapes: a triangle, a square, a circle, or an ellipse. In an embodiment, each of the first to third light emitting areas EA1, EA2, and EA3 has a rectangular planar shape. However, embodiments of the present disclosure are not necessarily limited thereto.

The light blocking area BA is positioned between the first to third light emitting areas EA1, EA2, and EA3. For example, the light blocking area BA surrounds the first to third light emitting areas EA1, EA2, and EA3 in a plan view. The light blocking area BA blocks light.

The peripheral area PA does not display an image. The peripheral area PA is positioned around the display area DA. For example, in an embodiment, the peripheral area PA entirely surrounds the display area DA.

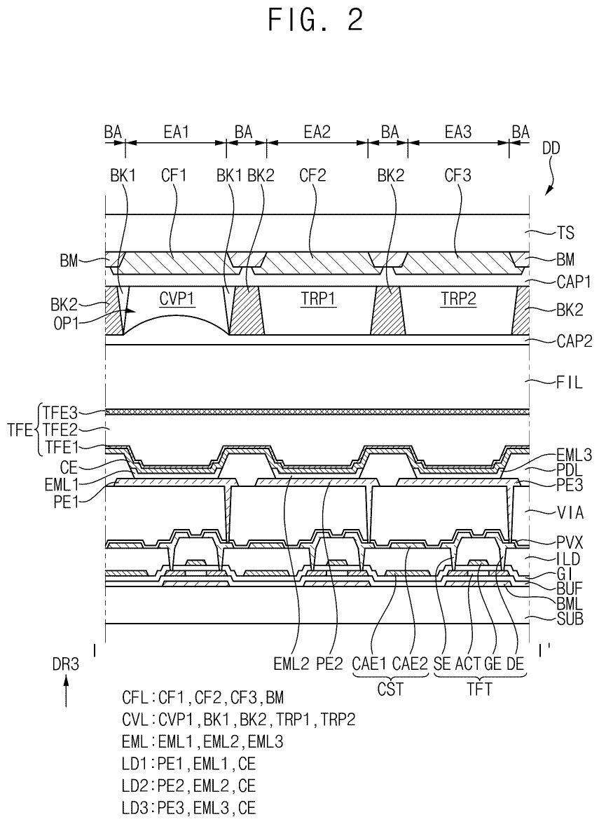

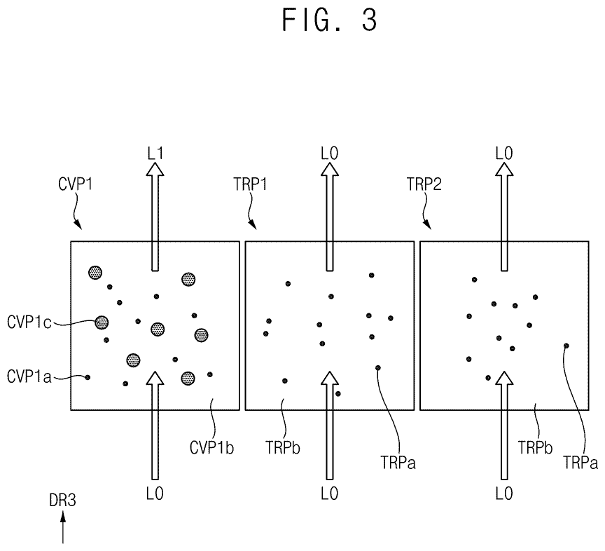

FIG. 2 is a cross-sectional view taken along line I-I′ of FIG. 1. FIG. 3 is a cross-sectional view of a color conversion layer in a display device of FIG. 2.

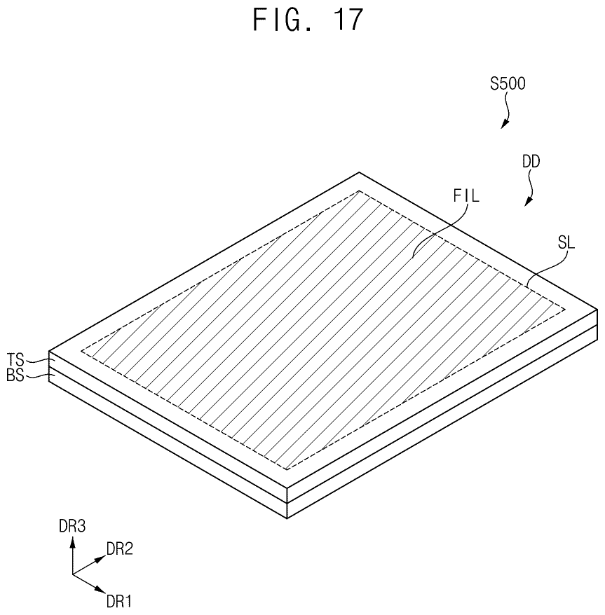

Referring to FIGS. 2 and 3, the display device DD according to an embodiment of the present disclosure includes an array substrate (ASUB, see FIG. 16), a color conversion substrate (CSUB, see FIG. 16), and a filling layer FIL disposed between the array substrate and the color conversion substrate.

The array substrate includes a substrate SUB, a lower pattern BML, a buffer layer BUF, a gate insulating layer GI, an inter-layer insulating layer ILD, a thin film transistor TFT, a storage capacitor CST, a protective layer PVX, a via-insulating layer VIA, a pixel defining layer PDL, first to third light emitting elements LD1, LD2, and LD3, and an encapsulation layer TFE.

The thin film transistor TFT includes an active pattern ACT, a gate electrode GE, a source electrode SE, and a drain electrode DE. The storage capacitor CST includes a first capacitor electrode CAE1 and a second capacitor electrode CAE2. The first light emitting element LD1 includes a first pixel electrode PE1, a first light emitting layer EML1, and a common electrode CE. The second light emitting element LD2 includes a second pixel electrode PE2, a second light emitting layer EML2, and the common electrode CE. The third light emitting element LD3 includes a third pixel electrode PE3, a third light emitting layer EML3, and the common electrode CE. A light emitting layer EML includes the first light emitting layer EML1, the second light emitting layer EML2, and the third light emitting layer EML3. The encapsulation layer TFE includes a first inorganic encapsulation layer TFE1, an organic encapsulation layer TFE2, and a second inorganic encapsulation layer TFE3.

The color conversion substrate includes an upper substrate TS, a color filter layer CFL, a first capping layer CAP1, a color conversion layer CVL, and a second capping layer CAP2. The color filter layer CFL includes first to third color filters CF1, CF2, and CF3 and a light blocking pattern BM. The color conversion layer CVL includes a first color conversion pattern CVP1, a first transmission pattern TRP1, a second transmission pattern TRP2, a first bank BK1, and a second bank BK2.

For example, the array substrate is formed from the light emitting layer EML, the encapsulation layer TFE, etc., on the substrate SUB, and the color conversion substrate is formed from the color filter layer CFL, the color conversion layer CVL, etc., on the upper substrate TS. The display device DD according to an embodiment of the present disclosure is formed by bonding the array substrate and the color conversion substrate.

The substrate SUB may include a transparent material or an opaque material. In an embodiment, the substrate SUB is formed of a transparent resin substrate. A polyimide substrate is an example of a transparent resin substrate. In other embodiments, the substrate SUB includes at least one of a quartz substrate, a synthetic quartz substrate, a calcium fluoride substrate, a fluorine-doped quartz substrate, a soda-lime glass substrate, a non-alkali glass substrate, etc. These can be used alone or in combination with each other.

The lower pattern BML is disposed on the substrate SUB. The lower pattern BML blocks external light from reaching the active pattern ACT. The lower pattern BML includes at least one of a metal, an alloy, a metal nitride, a conductive metal oxide, a transparent conductive material, etc. Examples of materials that can be used as the lower pattern BML include one or more of silver (Ag), an alloy that includes silver, molybdenum (Mo), an alloy that includes molybdenum, aluminum (Al), an alloy that includes aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These can be used alone or in combination with each other. In some embodiments, the lower pattern BML is omitted.

The buffer layer BUF is disposed on the substrate SUB and the lower pattern BML. The buffer layer BUF prevents diffusion of metal atoms or impurities from the substrate SUB to an upper structure, such as the thin film transistor TFT. The buffer layer BUF covers the lower pattern BML on the substrate SUB and is disposed along the profile of the lower pattern BML with a substantially uniform thickness. The buffer layer BUF includes an inorganic insulating material. Examples of an inorganic insulating material that can be used as the buffer layer BUF include at least one of silicon oxide (SiOₓ), silicon nitride (SiNₓ), silicon oxynitride (SiOₓN_{y}), etc. These can be used alone or in combination with each other.

The active pattern ACT is disposed on the buffer layer BUF. The active pattern ACT includes at least one of an oxide semiconductor, a silicon semiconductor, an organic semiconductor, etc. For example, the oxide semiconductor includes at least one of indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These can be used alone or in combination with each other. The silicon semiconductor includes at least one of amorphous silicon, polycrystalline silicon, etc. The active pattern ACT includes a source area, a drain area, and a channel area positioned between the source area and the drain area. In an embodiment, the active pattern ACT overlaps the lower pattern BML.

The gate insulating layer GI is disposed on the active pattern ACT and the buffer layer BUF. The gate insulating layer GI covers the active pattern ACT on the buffer layer BUF and is disposed along the profile of the active pattern ACT with a substantially uniform thickness. The gate insulating layer GI includes an inorganic insulating material. Examples of an inorganic insulating material that can be used as the gate insulating layer GI include at least one of silicon oxide (SiOₓ), silicon nitride (SiNₓ), silicon oxynitride (SiOₓN_{y}), etc. These can be used alone or in combination with each other. The gate insulating layer GI electrically insulates the active pattern ACT from the gate electrode GE.

The gate electrode GE and the first capacitor electrode CAE1 are disposed on the gate insulating layer GI. The gate electrode GE overlaps the channel area of the active pattern ACT in a plan view. The first capacitor electrode CAE1 is disposed in the same layer as the gate electrode GE. For example, the first capacitor electrode CAE1 and the gate electrode GE are formed of the same material and are formed through the same process. Each of the gate electrode GE and the first capacitor electrode CAE1 includes at least one of a metal, an alloy, a metal nitride, a conductive metal oxide, or a transparent conductive material. These can be used alone or in combination with each other.

The inter-layer insulating layer ILD is disposed on the gate insulating layer GI. The inter-layer insulating layer ILD covers the gate electrode GE and the first capacitor electrode CAE1 on the gate insulating layer GI. The inter-layer insulating layer ILD includes an inorganic insulating material. Examples of an inorganic insulating material that can be used as the inter-layer insulating layer ILD include at least one of silicon oxide (SiOₓ), silicon nitride (SiNₓ), silicon oxynitride (SiOₓN_{y}), etc. These can be used alone or in combination with each other. The inter-layer insulating layer ILD electrically insulates the gate electrode GE from the source electrode SE. In addition, the inter-layer insulating layer ILD electrically insulates the gate electrode GE from the drain electrode DE.

The source electrode SE, the drain electrode DE, and the second capacitor electrode CAE2 are disposed on the inter-layer insulating layer ILD. The source electrode SE is connected to the source area of the active pattern ACT through a contact hole that penetrates through the gate insulating layer GI and the inter-layer insulating layer ILD. The drain electrode DE is connected to the drain area of the active pattern ACT through a contact hole that penetrates through the gate insulating layer GI and the inter-layer insulating layer ILD. The second capacitor electrode CAE2 overlaps the first capacitor electrode CAE1 in a plan view. The second capacitor electrode CAE2 forms the storage capacitor CST together with the first capacitor electrode CAE1. The second capacitor electrode CAE2, the source electrode SE and the drain electrode DE are formed of the same material and are formed through the same process. Each of the source electrode SE, the drain electrode DE, and the second capacitor electrode CAE2 includes at least one of a metal, an alloy, a metal nitride, a conductive metal oxide, a transparent conductive material, etc. These can be used alone or in combination with each other.

Accordingly, the thin film transistor TFT, which includes the active pattern ACT, the gate electrode GE, the source electrode SE, and the drain electrode DE, is formed. In addition, the storage capacitor CST, which includes the first capacitor electrode CAE1 and the second capacitor electrode CAE2, is formed. The thin film transistor TFT and the storage capacitor CST are associated with each light emitting area EA1, EA2, and EA3.

The protective layer PVX is disposed on the inter-layer insulating layer ILD. The protective layer PVX covers the source electrode SE, the drain electrode DE, and the second capacitor electrode CAE2 on the inter-layer insulating layer ILD. The protective layer PVX protects the source electrode SE, the drain electrode DE, and the second capacitor electrode CAE from an etchant used to pattern the pixel electrode, such as the first pixel electrode PE1. The protective layer PVX includes an inorganic insulating material. Examples of an inorganic insulating material that can be used as the protective layer PVX include at least one of silicon oxide (SiOₓ), silicon nitride (SiNₓ), silicon oxynitride (SiOₓN_{y}), etc. These can be used alone or in combination with each other.

The via-insulating layer VIA is disposed on the protective layer PVX. The via-insulating layer VIA includes an organic insulating material. Examples of an organic insulating material that can be used as the via-insulating layer VIA include at least one of a photoresist, a polyacryl-based resin, a polyimide-based resin, a polyamide-based resin, a siloxane-based resin, an acryl-based resin, an epoxy-based resin, etc. These can be used alone or in combination with each other.

The first to third pixel electrodes PE1, PE2, and PE3 are disposed on the via-insulating layer VIA. The first pixel electrode PE1 overlaps the first light emitting area EA1, the second pixel electrode PE2 overlaps the second light emitting area EA2, and the third pixel electrode PE3 overlaps the third light emitting area EA3. Each of the first to third pixel electrodes PE1, PE2, and PE3 is connected to a drain electrode DE of a corresponding thin film transistor TFT through a contact hole that penetrates through the via-insulating layer VIA. Accordingly, each of the first to third pixel electrodes PE1, PE2, and PE3 is electrically connected to a corresponding thin film transistor TFT. Each of the first to third pixel electrodes PE1, PE2, and PE3 includes at least one of a metal, an alloy, a metal nitride, a conductive metal oxide, a transparent conductive material, etc. These can be used alone or in combination with each other. For example, each of the first to third pixel electrodes PE1, PE2, and PE3 is an anode electrode.

The pixel defining layer PDL is disposed on the via-insulating layer VIA. The pixel defining layer PDL covers an edge of each of the first to third pixel electrodes PE1, PE2, and PE3 and exposes a portion of an upper surface of each of the first to third pixel electrodes PE1, PE2, and PE3. The pixel defining layer PDL includes an organic insulating material. Examples of an organic insulating material that can be used as the pixel defining layer PDL include a photoresist, a polyacryl-based resin, a polyimide-based resin, a polyamide-based resin, a siloxane-based resin, an acryl-based resin, an epoxy-based resin, etc. These can be used alone or in combination with each other.

The light emitting layer EML is disposed on the first to third pixel electrodes PE1, PE2, and PE3. For example, the first light emitting layer EML1 is defined by the first pixel electrode PE1, the second light emitting layer EML2 is defined by the second pixel electrode PE2, and the third light emitting layer EML3 is defined by the third pixel electrode PE3. The first light emitting layer EML1 overlaps the first light emitting area EA1, the second light emitting layer EML2 overlaps the second light emitting area EA2, and the third light emitting layer EML3 overlaps the third light emitting area EA3.

In an embodiment, as illustrated in FIG. 2, the light emitting layer EML is disposed independently in each of the first to third light emitting areas EA1, EA2, and EA3. For example, the first light emitting layer EML1 is disposed in the first light emitting area EA1, the second light emitting layer EML2 is disposed in the second light emitting area EA2, and the third light emitting layer EML3 is disposed in the third light emitting area EA3. The first to third light emitting layers EML1, EML2, and EML3 are spaced apart from each other. However, embodiments of the present disclosure are not necessarily limited thereto. In other embodiments, the light emitting layer EML extends continuously along the first to third light emitting areas EA1, EA2, and EA3.

The light emitting layer EML includes an organic material that emits light of a predetermined color. For example, a hole provided by the pixel electrode PE and an electron provided by the common electrode CE combine in the light emitting layer EML to form an exciton, and the light emitting layer EML emits light as the exciton decays from an excited state to a ground state. The first to third light emitting layers EML1, EML2, and EML3 each emit light of the same color. In an embodiment, each of the first to third light emitting layers EML1, EML2, and EML3 emit green light and blue light. However, embodiments of the present disclosure are not necessarily limited thereto.

In an embodiment, each of the first to third light emitting layers EML1, EML2, and EML3 has a tandem structure in which a plurality of light emitting units are stacked. For example, when each of the first to third light emitting layers EML1, EML2, and EML3 emits green light and blue light, each of the first to third light emitting layers EML1, EML2, and EML3 includes a green light emitting unit that emits green light and a blue light emitting unit that is disposed on the green light emitting unit and emits blue light. However, embodiments of the stacking order of the light emitting units are not necessarily limited thereto, and in other embodiments, each of the first to third light emitting layers EML1, EML2, and EML3 includes a blue light emitting unit that emits blue light and a green light emitting unit that is disposed on the blue light emitting unit and emits green light.

The common electrode CE is disposed on the pixel defining layer PDL and the first to third light emitting layers EML1, EML2, and EML3. The common electrode CE includes at least one of a metal, an alloy, a metal nitride, a conductive metal oxide, a transparent conductive material, etc. They can be used alone or in combination with each other. For example, the common electrode CE is a cathode electrode.

Accordingly, the first light emitting element LD1, which includes the first pixel electrode PE1, the first light emitting layer EML1, and the common electrode CE, is formed. In addition, the second light emitting element LD2, which includes the second pixel electrode PE2, the second light emitting layer EML2, and the common electrode CE, is formed. In addition, the third light emitting element LD3, which includes the third pixel electrode PE3, the third light emitting layer EML3, and the common electrode CE, is formed.

The encapsulation layer TFE is disposed on the common electrode CE. The encapsulating layer TFE prevents impurities, moisture, etc., from penetrating into the first to third light emitting elements LD1, LD2, and LD3. The encapsulation layer TFE includes at least one inorganic encapsulation layer and at least one organic encapsulation layer. For example, the encapsulation layer TFE has a structure in which the first inorganic encapsulation layer TFE1, the organic encapsulation layer TFE2, and the second inorganic encapsulation layer TFE3 are sequentially stacked along the third direction DR3.

The first inorganic encapsulation layer TFE1 is disposed on the common electrode CE. The first inorganic encapsulation layer TFE1 covers the common electrode CE and is disposed along the profile of the common electrode CE with a uniform thickness. For example, the first inorganic encapsulation layer TFE1 includes a flexible inorganic insulating material.

The organic encapsulation layer TFE2 is disposed on the first inorganic encapsulation layer TFE1. The organic encapsulation layer TFE2 flattens the step of the first inorganic encapsulation layer TFE1. For example, the organic encapsulation layer TFE2 has a substantially flat upper surface. For example, the organic encapsulation layer TFE2 includes a flexible organic material.

The second inorganic encapsulation layer TFE3 is disposed on the organic encapsulation layer TFE2. The second inorganic encapsulation layer TFE3 covers the organic encapsulation layer TFE2 and is disposed along the profile of the organic encapsulation layer TFE2 with a uniform thickness. For example, the second inorganic encapsulation layer TFE3 includes an flexible inorganic insulating material.

The color filter layer CFL is disposed under the upper substrate TS that faces the substrate SUB. When the array substrate and the color conversion substrate are bonded, the color filter layer CFL is disposed on the color conversion layer CVL.

The upper substrate TS includes a transparent material. In an embodiment, the upper substrate TS includes at least one of glass or plastic. In an embodiment, the upper substrate TS includes an organic polymer material such as at least one of polycarbonate, polyethylene, polypropylene, etc. These can be used alone or in combination with each other.

The color filter layer CFL includes the light blocking pattern BM, the first color filter CF1, the second color filter CF2, and the third color filter CF3. The light blocking pattern BM partitions the first to third light emitting areas EA1, EA2, and EA3. For example, the light blocking pattern BM forms a plurality of openings that partition the first to third light emitting areas EA1, EA2, and EA3. Accordingly, the light blocking pattern BM overlaps the blocking area BA and does not overlap the first to third light emitting areas EA1, EA2, and EA3. The light blocking pattern BM includes an inorganic material and/or an organic material that includes a black light blocking material. For example, the light blocking pattern BM includes at least one of a black pigment, a black dye, carbon black, etc. These can be used alone or in combination with each other.

The first to third color filters CF1, CF2, and CF3 are disposed in the openings formed by the light blocking pattern BM. The first color filter CF1 overlaps the first light emitting area EA1. For example, the first color filter CF1 transmits red light and absorbs or blocks green light and blue light. The second color filter CF2 overlaps the second light emitting area EA2. For example, the second color filter CF2 transmits green light, and absorbs or blocks red light and blue light. The third color filter CF3 overlaps the third light emitting area EA3. The third color filter CF3 transmits blue light, and absorbs or blocks red light and green light.

The first color filter CF1 is spaced apart from the second color filter CF2 by the light blocking area BA, and the second color filter CF2 is spaced apart from the third color filter CF3 by the light blocking area BA. However, embodiments of the present disclosure are not necessarily limited thereto, and in some embodiments, the first color filter CF1 contact the second color filter CF2 in the light blocking area BA, and the second color filter CF2 contacts the third color filter CF3 in the light blocking area BA.

The first capping layer CAP1 is disposed under the color filter layer CFL. The first capping layer CAP1 is entirely disposed over the first to third light emitting areas EA1, EA2, and EA3 and the light blocking area BA. The first capping layer CAP1 prevents moisture penetration and deterioration of the color filter layer CFL. In addition, the first capping layer CAP1 flattens step differences of the color filter layer CFL. The first capping layer CAP1 may include an inorganic insulating material and/or an organic insulating material.

The color conversion layer CVL is disposed under the first capping layer CAP1. When the array substrate and the color conversion substrate are bonded, the color conversion layer CVL is disposed on the light emitting layer EML. The color conversion layer CVL includes the first color conversion pattern CVP1, the first transmission pattern TRP1, the second transmission pattern TRP2, the first bank BK1, and the second bank BK2.

The first bank BK1 is disposed under the first capping layer CAP1. When the array substrate and the color conversion substrate are bonded, the first bank BK1 is disposed in the first light emitting area EA1 on the light emitting layer EML. For example, the first bank BK1 overlaps a portion of the first light emitting area EA1 and a portion of the light blocking area BA adjacent to the first light emitting area EA1.

In an embodiment, the first bank BK1 overlaps an edge of the first light emitting layer EML1 in a plan view, such as a portion adjacent to the pixel defining layer PDL, and overlaps an edge of the first color filter CF1 in a plan view, such as a portion adjacent to the light blocking pattern BM. In addition, the first bank BK1 overlaps an edge of the pixel defining layer PDL that surrounds the first light emitting layer EML1 in a plan view. The first bank BK1 has a first opening OP1 that exposes a central portion of the first light emitting layer EML1. For example, the first opening OP1 of the first bank BK1 accommodates an ink composition. The first bank BK1 includes scattering particles and a photosensitive polymer in which the scattering particles are dispersed.

In another embodiment, when the light emitting layer EML extends continuously along the first to third light emitting areas EA1, EA2, and EA3, the first bank BK1 overlaps with an edge of the first color filter CF1 in a plan view. For example, the first opening OP1 of the first bank BK1 exposes a central portion of the first color filter CF1.

The second bank BK2 is disposed under the first capping layer CAP1. For example, when the array substrate and the color conversion substrate are bonded, the second bank BK2 is disposed in the light blocking area BA between the light emitting layers EML. The second bank BK2 contacts a side surface of the first bank BK1. The second bank BK2 has a grid shape or a matrix shape in a plan view. The second bank BK2 includes a different material from the first bank BK1. For example, the second bank BK2 includes an organic material and/or an inorganic material that includes a black light blocking material. In an embodiment, the second bank BK2 includes carbon black.

In an embodiment, the second bank BK2 further includes a liquid-repellent material. For example, the liquid-repellent material may be a fluorine-based compound or a siloxane-based compound, etc. The liquid-repellent material is disposed on a surface of the second bank BK2. For example, the liquid-repellent material covers the surface of the second bank BK2. Accordingly, the surface of the second bank BK2 is liquid-repellent. Since the surface of the second bank BK2 is liquid-repellent, the first color conversion pattern CVP1 can be more smoothly formed in the first opening OP1.

The first color conversion pattern CVP1 is disposed inside the first opening OP1 of the first bank BK1. For example, the first color conversion pattern CVP1 is formed inside the first opening OP1 through an inkjet printing method. Accordingly, a thickness of the first color conversion pattern CVP1 may increase from a central portion of the first color conversion pattern CVP1 toward the first bank BK1. The first color conversion pattern CVP1 overlaps the first light emitting layer EML1 and the first color filter CF1 in the first light emitting area EA1 in a plan view.

The first transmission pattern TRP1 is disposed under the first capping layer CAP1 and contacts a side surface of the second bank BK2. For example, the first transmission pattern TRP1 is surrounded by the second bank BK2 in a plan view. The first transmission pattern TRP1 overlaps the second light emitting layer EML2 and the second color filter CF2 in the second light emitting area EA2 in a plan view.

The second transmission pattern TRP2 is disposed under the first capping layer CAP1 and contacts a side surface of the second bank BK2. For example, the second transmission pattern TRP2 is surrounded by the second bank BK2 in a plan view. The second transmission pattern TRP2 overlaps the third light emitting layer EML3 and the third color filter CF3 in the third light emitting area EA3 in a plan view.

As illustrated in FIG. 3, in an embodiment, the first color conversion pattern CVP1 converts light L0 emitted from the light emitting layer EML into light L1 of a first color. The first color conversion pattern CVP1 includes first quantum dots CVP1c that are excited by the light L0 emitted from the light emitting layer EML and emit the light L1 of the first color. In addition, the first color conversion pattern CVP1 further includes a first photosensitive polymer CVP1b in which first scattering particles CVP1a are dispersed. In an embodiment, the light L0 emitted from the light emitting layer EML is a mixture of blue light and green light, and the first color is red. Light passing through the first color conversion pattern CVP1 is incident on the first color filter CF1. The first color filter CF1 transmits red light, and absorbs green light and blue light. Accordingly, red light is emitted from the first light emitting area EA1. However, embodiments of the present disclosure are not necessarily limited thereto.

The first transmission pattern TRP1 transmits light L0 emitted from the light emitting layer EML. The first transmission pattern TRP1 includes a second photosensitive polymer TRPb in which second scattering particles TRPa are dispersed. Light passing through the first transmission pattern TRP1 is incident on the second color filter CF2. The second color filter CF2 transmits green light and absorbs red light and blue light. Accordingly, green light is emitted from the second light emitting area EA2. However, embodiments of the present disclosure are not necessarily limited thereto.

The second transmission pattern TRP2 transmits light L0 emitted from the light emitting layer EML. The second transmission pattern TRP2 includes the second photosensitive polymer TRPb in which the second scattering particles TRPa are dispersed. For example, the second transmission pattern TRP2 and the first transmission pattern TRP1 include the same material and are formed through the same process. In an embodiment, the first transmission pattern TRP1, the second transmission pattern TRP2, and the first bank BK1 include the same material and are formed through the same process. Light passing through the second transmission pattern TRP2 is incident on the third color filter CF3. The third color filter CF3 transmits blue light and absorbs red light and green light. Accordingly, blue light is emitted from the third light emitting area EA3. However, embodiments of the present disclosure are not necessarily limited thereto.

For example, each of the first photosensitive polymer CVP1b and the second photosensitive polymer TRPb include a light transmitting organic material such as silicone resin, epoxy resin, etc. The first scattering particles CVP1a and the second scattering particles TRPa scatter light L0 emitted from the light emitting layer EML.

The second capping layer CAP2 is disposed under the color conversion layer CVL. The second capping layer CAP2 is entirely disposed over the first to third light emitting areas EA1, EA2, and EA3 and the light blocking area BA. The second capping layer CAP2 covers and protects the color conversion layer CVL. In addition, the second capping layer CAP2 flattens step differences of the color conversion layer CVL. The second capping layer CAP2 may include an inorganic insulating material and/or an organic insulating material.

The filling layer FIL is disposed between the substrate SUB and the upper substrate TS. For example, the filling layer FIL is disposed between the array substrate and the color conversion substrate. The filling layer FIL fills a space between the array substrate and the color conversion substrate. For example, the filling layer FIL fills a space between the second capping layer CAP2 and the encapsulation layer TFE. The filling layer FIL includes a light transmitting material. For example, the filling layer FIL includes an organic material.

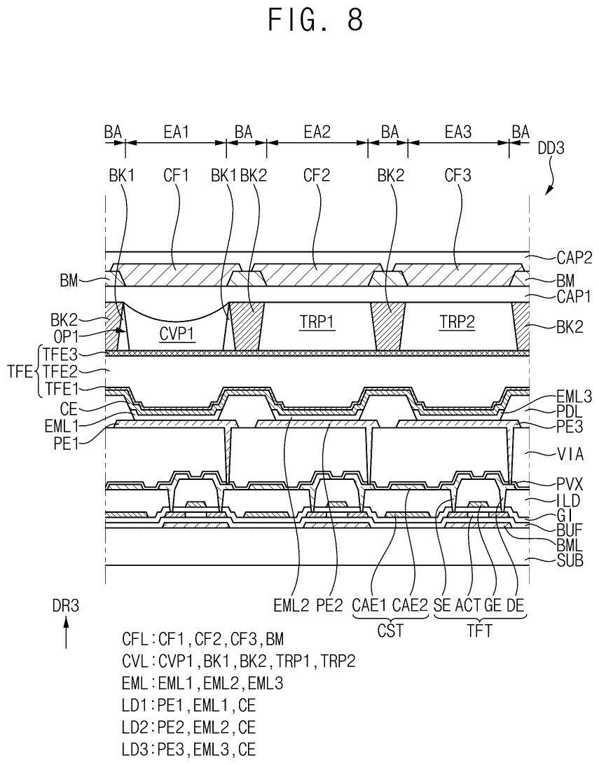

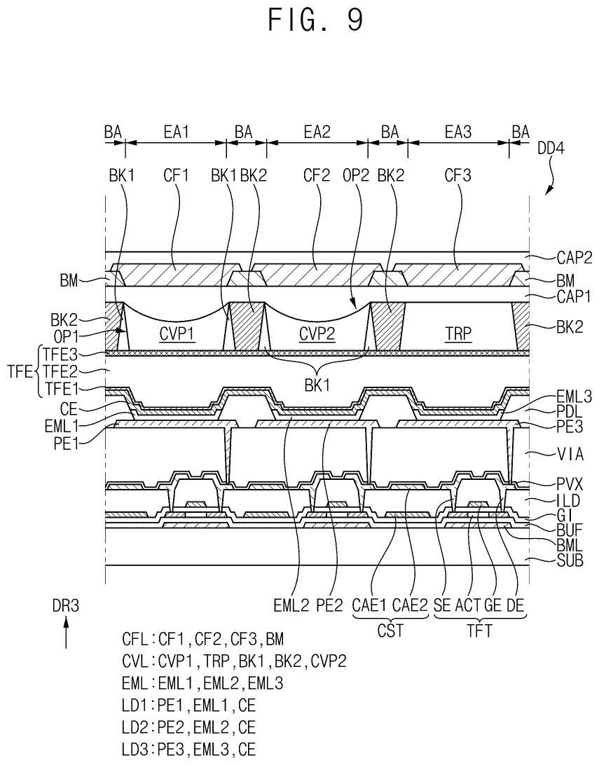

FIG. 2 illustrates the display device DD as having a structure that includes two substrates, such as the substrate SUB and the upper substrate TS, but embodiments of the present disclosure are not necessarily limited thereto. For example, in an embodiment, a display device has a structure that includes one substrate. This will be described below with reference to FIGS. 8 and 9.

Since the first bank BK1 includes scattering particles, the first bank BK1 reflects or scatters light incident from the light emitting layer EML. In addition, the first bank BK1 reflects or scatters light incident from the first color conversion pattern CVP1. The light reflected or scattered from the first bank BK1 is incident on the first color conversion pattern CVP1. For example, the light reflected or scattered from the first bank BK1 is reused in the first color conversion pattern CVP1, and thus light efficiency increases in the first light emitting area EA1.

Since the second bank BK2 includes a black organic and/or inorganic material, the second bank BK2 blocks or absorbs light incident from a light emitting layer, such as the second light emitting layer EML2, that is adjacent to the first light emitting layer EML1.

In an embodiment, the second bank BK2 includes carbon black. Since the second bank BK2 includes carbon black, as compared to a light blocking bank formed by mixing black pigment with other pigments, the second bank BK2 effectively blocks or absorbs light incident from the adjacent light emitting layers. Accordingly, a color mixing phenomenon that can occur between adjacent sub-pixels is reduced.

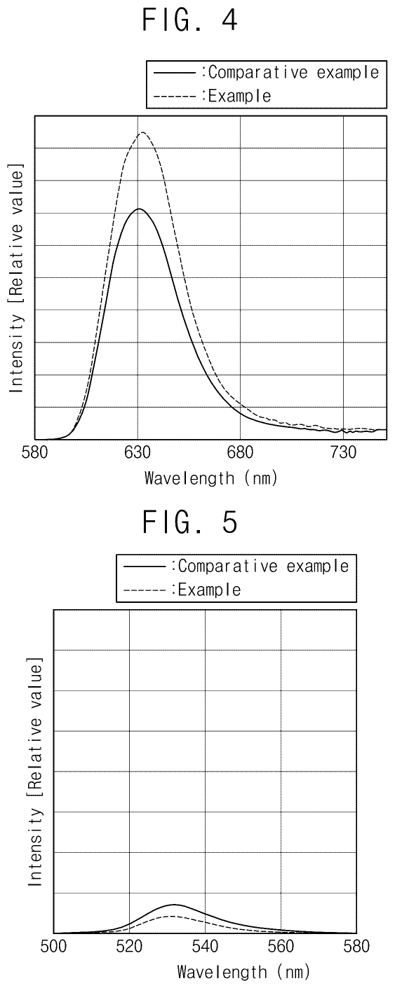

FIGS. 4 and 5 illustrate light intensity as a function of a wavelength of light emitted from a display device of FIG. 2. Hereinafter, effects of an embodiment of the present disclosure will be described with reference to FIGS. 2, 4, and 5.

An intensity of light as a function of a wavelength of light was measured in display devices satisfying a Comparative example and an Example. For example, in display devices satisfying the Comparative example and the Example, the intensity of light as a function of the wavelength of light was measured in the first light emitting area EA1 where red light is emitted.

A display device satisfying the Example, such as the display device DD of FIG. 2, includes the first bank BK1 disposed in the first light emitting area EA1 on the light emitting layer EML and that overlaps the edge of the first light emitting layer EML in a plan view, and the second bank BK2 disposed in the light blocking area BA on the light emitting layer EML and that contacts the side surface of the first bank BK1. The first bank BK1 includes scattering particles, and the second bank BK2 includes carbon black.

A display device satisfying the Comparative example includes a light blocking bank disposed in the light blocking area BA on the light emitting layer EML, but does not include the first bank BK1 that overlaps the edge of the first light emitting layer EML1 in a plan view. The light blocking bank includes a material mixed with black pigment and other pigments.

As a result, as illustrated in FIG. 4, for the first light, such as red light, that has a wavelength of about 630 nanometers, based on the intensity of the first light emitted from the first light emitting area EA1 of the display device that satisfies the Comparative example, the intensity of the first light emitted from the first light emitting area EA1 of the display device that satisfies the Example was measured to have a value of about 131.7%. From these results, the display device DD according to an embodiment of the present disclosure has a relatively increased light efficiency by including the first bank BK1 that overlaps the edge of the first light emitting layer EML1 in a plan view and includes scattering particles.

In addition, as illustrated in FIG. 5, for the second light, such as green light, that has a wavelength of about 530 nanometers, based on the intensity of the second light emitted from the first light emitting area EA1 of the display device that satisfies the Comparative example, the intensity of the second light emitted from the first light emitting area EA1 of the display device that satisfies the Example was measured to have a value of about 52.3%. From these results, a color mixing phenomenon between adjacent sub-pixels in the display device DD is relatively reduced by including the second bank BK2 in the light blocking area BA on the light emitting layer EML and that includes carbon black.

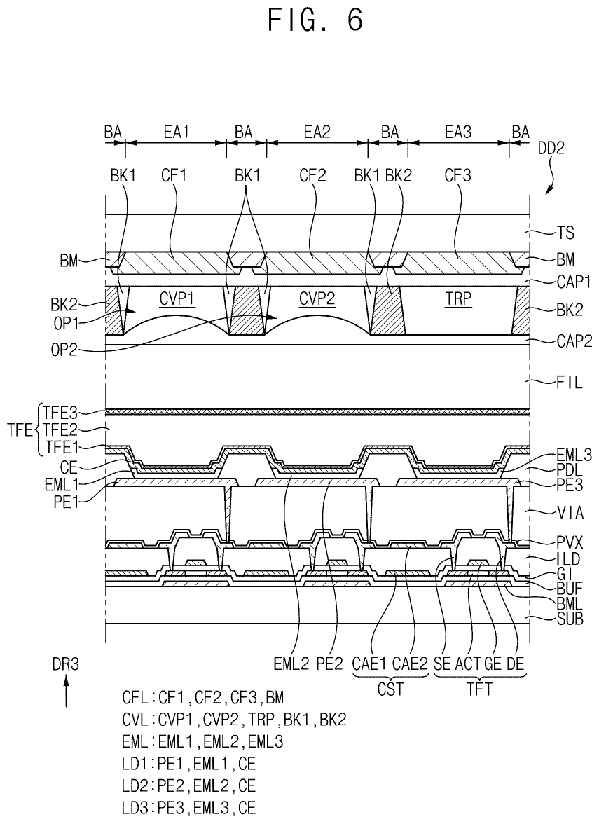

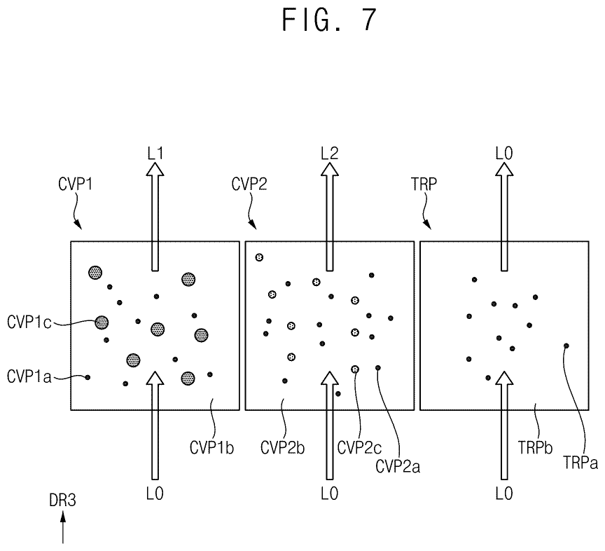

FIG. 6 is a cross-sectional view of a display device according to an embodiment of the present disclosure. FIG. 7 is a cross-sectional view of a color conversion layer in the display device of FIG. 6.

Referring to FIGS. 6 and 7, a display device DD2 according to an embodiment of the present disclosure includes an array substrate (ASUB, see FIG. 16), a color conversion substrate, and the filling layer FIL disposed between the array substrate and the color conversion substrate.

The array substrate is substantially the same as the array substrate of the display device DD described with reference to FIG. 2.

The color conversion substrate includes the upper substrate TS, the color filter layer CFL, the first capping layer CAP1, a color conversion layer CVL, and the second capping layer CAP2. The color filter layer CFL includes the first to third color filters CF1, CF2, and CF3 and the light blocking pattern BM. The color conversion layer CVL includes the first color conversion pattern CVP1, a second color conversion pattern CVP2, a transmission pattern TRP, a first bank BK1, and a second bank BK2.

The display device DD2 is substantially the same as the display device DD described with reference to FIGS. 1, 2, and 3, except that the first bank BK1 is further disposed in the second light emitting area EA2 on the light emitting layer EML, and the second color conversion pattern CVP2 is disposed inside a second opening OP2 formed in the first bank BK1. Accordingly, hereinafter, redundant descriptions of the display device DD described above with reference to FIGS. 1, 2, and 3 may be omitted or summarized.

The color filter layer CFL is disposed under the upper substrate TS, the first capping layer CAP1 is disposed under the color filter layer CFL, and the color conversion layer CVL is disposed under the first capping layer CAP1. For example, when the array substrate and the color conversion substrate are bonded, the color conversion layer CVL is disposed on the light emitting layer EML. The color conversion layer CVL includes the first color conversion pattern CVP1, the second color conversion pattern CVP2, the transmission pattern TRP, the first bank BK1, and the second bank BK2.

The first bank BK1 is disposed under the first capping layer CAP1. For example, when the array substrate and the color conversion substrate are bonded, the first bank BK1 is disposed in the first light emitting area EA1 and the second light emitting area EA2 on the light emitting layer EML. For example, the first bank BK1 overlaps a portion of the first light emitting area EA1 and a portion of the light blocking area BA adjacent to the first light emitting area EA1. In addition, the first bank BK1 overlaps a portion of the second light emitting area EA2 and a portion of the light blocking area BA adjacent to the second light emitting area EA2.

In an embodiment, the first bank BK1 overlaps, in a plan view, an edge of the first light emitting layer EML1 and an edge of the second light emitting layer EML2. In addition, the first bank BK1 overlaps, in a plan view, an edge of the pixel defining layer PDL that surrounds the first light emitting layer EML1, and an edge of the pixel defining layer PDL that surrounds the second light emitting layer EML2. The first bank BK1 includes a first opening OP1 that exposes a central portion of the first light emitting layer EML1, and a second opening OP2 that exposes a central portion of the second light emitting layer EML2. For example, the first bank BK1 includes the first opening OP1 and the second opening OP2 that accommodate an ink composition. The first bank BK1 includes scattering particles and a photosensitive polymer in which the scattering particles are dispersed.

In an embodiment, when the light emitting layer EML extends continuously along the first to third light emitting areas EA1, EA2, and EA3, the first bank BK1 overlaps an edge of the first color filter CF1 and an edge of the second color filter CF2 in a plan view. For example, the first bank BK1 includes the first opening OP1 that exposes a central portion of the first color filter CF1 and the second opening OP2 that exposes a central portion of the second color filter CF2.

The second bank BK2 is disposed under the first capping layer CAP1. For example, when the array substrate and the color conversion substrate are bonded, the second bank BK2 is disposed in the light blocking area BA between the light emitting layers EML. The second bank BK2 contacts a side surface of the first bank BK1. The second bank BK2 includes a different material from the first bank BK1. In an embodiment, the second bank BK2 includes carbon black.

The first color conversion pattern CVP1 is disposed inside the first opening OP1 of the first bank BK1. The first color conversion pattern CVP1 overlaps, in a plan view, the first light emitting layer EML1 and the first color filter CF1 in the first light emitting area EA1.

The second color conversion pattern CVP2 is disposed inside the second opening OP2 of the first bank BK1. For example, the second color conversion pattern CVP2 is formed inside the second opening OP2 through an inkjet printing method. The second color conversion pattern CVP2 overlaps, in a plan view. the second light emitting layer EML2 and the second color filter CF2 in the second light emitting area EA2.

The transmission pattern TRP is disposed under the first capping layer CAP1 and contacts a side surface of the second bank BK2. For example, the transmission pattern TRP is surrounded by the second bank BK2 in a plan view. The transmission pattern TRP overlaps, in a plan view, the third light emitting layer EML3 and the third color filter CF3 in the third light emitting area EA3.

As illustrated in FIG. 7, the first color conversion pattern CVP1 converts light L0 emitted from the light emitting layer EML into light L1 of a first color. In an embodiment, the light L0 emitted from the light emitting layer EML is a mixture of blue light and green light, and the first color is red. Light passing through the first color conversion pattern CVP1 is incident on the first color filter CF1. The first color filter CF1 transmits red light, and absorbs green light and blue light. Accordingly, red light is emitted from the first light emitting area EA1. In an embodiment, the light L0 emitted from the light emitting layer EML includes only blue light, but not green light.

The second color conversion pattern CVP2 converts the light L0 emitted from the light emitting layer EML into light L2 of a second color. The second color conversion pattern CVP2 includes second quantum dots CVP2c that are excited by the light L0 emitted from the light emitting layer EML and emit the light L2 of the second color. In addition, the second color conversion pattern CVP2 further includes a third photosensitive polymer CVP2b in which third scattering particles CVP2a are dispersed.

In an embodiment, the light L0 emitted from the light emitting layer EML is a mixture of blue light and green light, and the second color is green. For example, the second color conversion pattern CVP2 converts the blue light of the light L0 emitted from the light emitting layer EML into green light. Light passing through the second color conversion pattern CVP2 is incident on the second color filter CF2. The second color filter CF2 transmits green light and absorbs red light and blue light. Accordingly, green light is emitted from the second light emitting area EA2. For example, since the second color conversion pattern CVP2 converts blue light of the light L0 emitted from the light emitting layer EML into green light, the amount of light absorbed by the second color filter CF2 is relatively reduced. Since the amount of light absorbed by the second color filter CF2 is relatively reduced, the light efficiency in the second light emitting area EA2 increases. In an embodiment, the light L0 emitted from the light emitting layer EML includes only blue light, but not green light.

The transmission pattern TRP transmits the light L0 emitted from the light emitting layer EML. Light passing through the transmission pattern TRP is incident on the third color filter CF3. The third color filter CF3 transmits blue light and absorbs red light and green light. Accordingly, blue light is emitted from the third light emitting area EA3.

Since the first bank BK1 includes scattering particles, the first bank BK1 reflects or scatter light incident from the light emitting layer EML. In addition, the first bank BK1 reflects or scatters light incident from the first color conversion pattern CVP1, and reflects or scatters light incident from the second color conversion pattern CVP2.

The light reflected or scattered from the first bank BK1 that overlaps the first light emitting area EA1 is reused in the first color conversion pattern CVP1, and thus light efficiency increases in the first light emitting area EA1. In addition, the light reflected or scattered from the first bank BK1 that overlaps the second light emitting area EA2 is reused in the second color conversion pattern CVP2, and thus light efficiency increases in the second light emitting area EA2.

FIG. 8 is a cross-sectional view illustrating a display device according to an embodiment of the present disclosure.

Referring to FIG. 8, a display device DD3 according to an embodiment of the present disclosure includes the substrate SUB, the lower pattern BML, the buffer layer BUF, the gate insulating layer GI, the inter-layer insulating layer ILD, the thin film transistor TFT, the storage capacitor CST, the protective layer PVX, the via-insulating layer VIA, the pixel defining layer PDL, the first to third light emitting elements LD1, LD2, and LD3, the encapsulation layer TFE, a color conversion layer CVL, a first capping layer CAP1, a color filter layer CFL, and a second capping layer CAP2.

The display device DD3 is substantially the same as the display device DD described with reference to FIGS. 1 to 3, except that the display device DD3 includes a single substrate and the color conversion layer CVL is disposed directly on the encapsulation layer TFE. Accordingly, hereinafter, redundant descriptions of the display device DD described above with reference to FIGS. 1 to 3 may be omitted or summarized.

The color conversion layer CVL is disposed on the light emitting layer EML. For example, the color conversion layer CVL is disposed on the encapsulation layer TFE. The color conversion layer CVL includes a first color conversion pattern CVP1, a first transmission pattern TRP1, a second transmission pattern TRP2, a first bank BK1, and a second bank BK2.

The first bank BK1 is disposed on the encapsulation layer TFE. The first bank BK1 is disposed in the first light emitting area EA1 on the light emitting layer EML. The first bank BK1 overlaps an edge of the first light emitting layer EML1 in a plan view. The first bank BK1 includes a first opening OP1 that exposes a central portion of the first light emitting layer EML1. The first bank BK1 includes scattering particles and a photosensitive polymer in which the scattering particles are dispersed.

The second bank BK2 is disposed on the encapsulation layer TFE. The second bank BK2 is disposed in the light blocking area BA between the light emitting layers EML. The second bank BK2 contacts a side surface of the first bank BK1. The second bank BK2 includes a different material from the first bank BK1. In an embodiment, the second bank BK2 includes carbon black.

The first color conversion pattern CVP1 is disposed inside a first opening OP1 formed in the first bank BK1. The first color conversion pattern CVP1 overlaps, in a plan view, the first light emitting layer EML1 and the first color filter CF1 in the first light emitting area EA1. The first color conversion pattern CVP1 converts light emitted from the light emitting layer EML into light of a first color. In an embodiment, the light emitted from the light emitting layer EML is a mixture of blue light and green light, and the first color is red. However, embodiments of the present disclosure are not necessarily limited thereto.

The first transmission pattern TRP1 is disposed on the encapsulation layer TFE and contacts a side surface of the second bank BK2. The first transmission pattern TRP1 overlaps, in a plan view, the second light emitting layer EML2 and the second color filter CF2 in the second light emitting area EA2. The first transmission pattern TRP1 transmits light emitted from the light emitting layer EML.

The second transmission pattern TRP2 is disposed on the encapsulation layer TFE and contacts a side surface of the second bank BK2. The second transmission pattern TRP2 overlaps, in a plan view, the third light emitting layer EML3 and the third color filter CF3 in the third light emitting area EA3. The second transmission pattern TRP2 transmits light emitted from the light emitting layer EML.

The first capping layer CAP1 is disposed on the color conversion layer CVL. The first capping layer CAP1 is entirely disposed on the first to third light emitting areas EA1, EA2, and EA3 and the light blocking area BA. The first capping layer CAP1 covers and protects the color conversion layer CVL. In addition, the first capping layer CAP1 flattens step differences of the color conversion layer CVL. The first capping layer CAP1 may include an inorganic insulating material and/or an organic insulating material.

The color filter layer CFL is disposed on the first capping layer CAP1, and the second capping layer CAP2 is disposed on the color filter layer CFL. The second capping layer CAP2 is entirely disposed on the first to third light emitting areas EA1, EA2, and EA3 and the light blocking area BA. The second capping layer CAP2 prevents moisture penetration and deterioration of the color filter layer CFL. In addition, the second capping layer CAP2 flattens step differences of the color filter layer CFL. The second capping layer CAP2 may include an inorganic insulating material and/or an organic insulating material.

FIG. 9 is a cross-sectional view of a display device according to an embodiment of the present disclosure.

Referring to FIG. 9, a display device DD4 according to an embodiment of the present disclosure includes the substrate SUB, the lower pattern BML, the buffer layer BUF, the gate insulating layer GI, the inter-layer insulating layer ILD, the thin film transistor TFT, the storage capacitor CST, the protective layer PVX, the via-insulating layer VIA, the pixel defining layer PDL, the first to third light emitting elements LD1, LD2, and LD3, the encapsulation layer TFE, a color conversion layer CVL, the first capping layer CAP1, the color filter layer CFL, and the second capping layer CAP2.

The display device DD4 is substantially the same as the display device DD2 described with reference to FIGS. 6 and 7, except that the display device DD4 includes a single substrate and the color conversion layer CVL is disposed directly on the encapsulation layer TFE. In addition, the display device DD4 is substantially the same as the display device DD3 described with reference to FIG. 8, except that a first bank BK1 is further disposed in the second light emitting area EA2 on the light emitting layer EML, and a second color conversion pattern CVP2 is disposed inside a second opening OP2 of the first bank BK1. Accordingly, hereinafter, redundant descriptions of the display device DD2 described above with reference to FIGS. 6 and 7 and redundant descriptions of the display device DD3 described above with reference to FIG. 8 may be omitted or summarized.

The color conversion layer CVL is disposed on the light emitting layer EML. For example, the color conversion layer CVL is disposed on the encapsulation layer TFE. The color conversion layer CVL includes a first color conversion pattern CVP1, the second color conversion pattern CVP2, a transmission pattern TRP, the first bank BK1, and a second bank BK2.

The first bank BK1 is disposed on the encapsulation layer TFE. The first bank BK1 is disposed in the first light emitting area EA1 and the second light emitting area EA2 on the light emitting layer EML. The first bank BK1 overlaps, in a plan view, an edge of the first light emitting layer EML1 and an edge of the second light emitting layer EML2. The first bank BK1 includes a first opening OP1 that exposes a central portion of the first light emitting layer EML1, and the second opening OP2 that exposes a central portion of the second light emitting layer EML2. The first bank BK1 includes scattering particles and a photosensitive polymer in which the scattering particles are dispersed.

The second bank BK2 is disposed on the encapsulation layer TFE. The second bank BK2 is disposed in the light blocking area BA between the light emitting layers EML. The second bank BK2 contacts a side surface of the first bank BK1. The second bank BK2 includes a different material from the first bank BK1. In an embodiment, the second bank BK2 includes carbon black.

The first color conversion pattern CVP1 is disposed inside the first opening OP1 of the first bank BK1. The first color conversion pattern CVP1 overlaps, in a plan view, the first light emitting layer EML1 and the first color filter CF1 in the first light emitting area EA1. The first color conversion pattern CVP1 converts light emitted from the light emitting layer EML into light of a first color. In an embodiment, the light emitted from the light emitting layer EML is a mixture of blue light and green light, and the first color is red. In an embodiment, the light emitted from the light emitting layer EML includes only blue light, but not green light.

The second color conversion pattern CVP2 is disposed inside the second opening OP2 of the first bank BK1. The second color conversion pattern CVP2 overlaps, in a plan view, the second light emitting layer EML2 and the second color filter CF2 in the second light emitting area EA2. The second color conversion pattern CVP2 converts the light emitted from the light emitting layer EML into light of a second color. In an embodiment, the light emitted from the light emitting layer EML is a mixture of blue light and green light, and the second color is green. In an embodiment, the light emitted from the light emitting layer EML includes only blue light, but not green light.

The transmission pattern TRP is disposed on the encapsulation layer TFE and contacts a side surface of the second bank BK2. The transmission pattern TRP overlaps, in a plan view, the third light emitting layer EML3 and the third color filter CF3 in the third light emitting area EA3. The transmission pattern TRP transmits the light emitted from the light emitting layer EML.

The first capping layer CAP1 is disposed on the color conversion layer CVL, the color filter layer CFL is disposed on the first capping layer CAP1, and the second capping layer CAP2 is disposed on the color filter layer CFL.

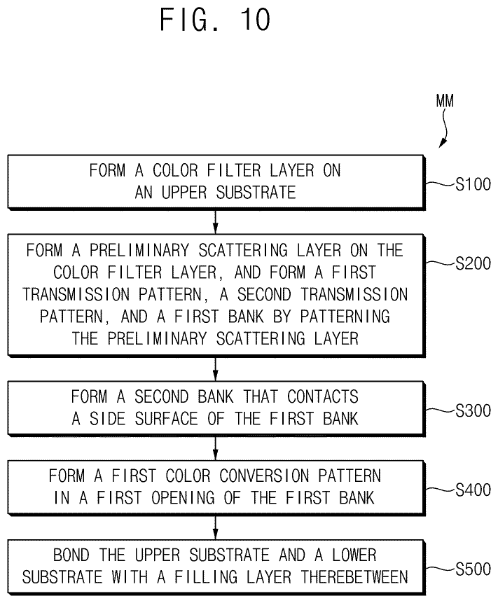

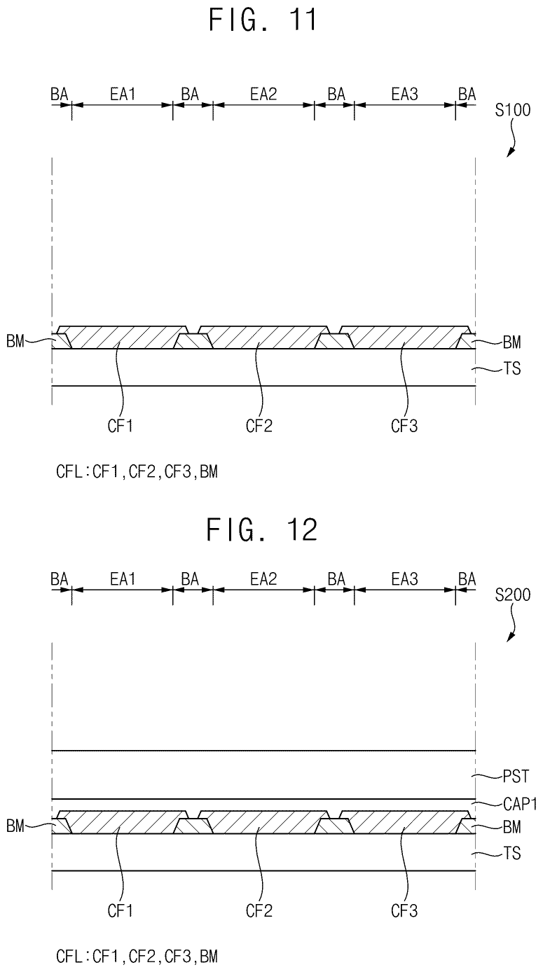

FIG. 10 is a flowchart of a method of manufacturing a display device according to an embodiment of FIG. 1. FIGS. 11, 12, 13, 14, 15, 16, 17, and 18 illustrate a method of manufacturing the display device of FIG. 10.

A method MM of manufacturing a display device described below with reference to FIGS. 11 to 18 manufactures the display device DD described above with reference to FIGS. 1, 2, and 3. Accordingly, redundant descriptions of the display device DD described above with reference to FIGS. 1, 2, and 3 may be omitted or summarized.

A method of manufacturing the display device DD2 described above with reference to FIGS. 6 and 7 is substantially the same as a method of manufacturing the display device DD described above with reference to FIGS. 1, 2, and 3, except that the first bank BK1 is further formed in the second light emitting area EA2 on the color filter layer CFL, and the second color conversion pattern CVP2 is formed inside the second opening OP2 of the first bank BK1 in the second light emitting area EA2. Accordingly, a description of a method of manufacturing the display device DD2 described above with reference to FIGS. 6 and 7 will be omitted.

Referring to FIG. 10, a method MM of manufacturing a display device according to an embodiment of the present disclosure includes forming a color filter layer on an upper substrate (S100), forming a preliminary scattering layer on the color filter layer, and forming a first transmission pattern, a second transmission pattern, and a first bank by patterning the preliminary scattering layer (S200), forming a second bank that contacts a side surface of the first bank (S300), forming a first color conversion pattern in a first opening of the first bank (S400), and bonding the upper substrate and a lower substrate with a filling layer therebetween (S500).

Referring to FIG. 11, in an embodiment, a color filter layer CFL is formed on an upper substrate TS (S100).

The upper substrate TS includes first to third light emitting areas EA1, EA2, and EA3 and a light blocking area BA. The light blocking area BA surrounds the first to third light emitting areas EA1, EA2, and EA3.

The color filter layer CFL is formed on the upper substrate TS. The color filter layer CFL includes first to third color filters CF1, CF2, and CF3 and a light blocking pattern BM.

The light blocking pattern BM is formed to overlap the light blocking area BA. The light blocking pattern BM includes a plurality of openings that partition the first to third light emitting areas EA1, EA2, and EA3.

After the light blocking pattern BM is formed, the first to third color filters CF1, CF2, and CF3 are formed on the upper substrate TS. The first color filter CF1 overlaps the first light emitting area EA1, the second color filter CF2 overlaps the second light emitting area EA2, and the third color filter CF3 overlaps the third light emitting area EA3.

Referring to FIG. 12, in an embodiment, a preliminary scattering layer PST and a first capping layer CAP1 are formed on the color filter layer CFL (S200).

The first capping layer CAP1 is formed on the color filter layer CFL. The first capping layer CAP1 is entirely formed on the first to third light emitting areas EA1, EA2, and EA3 and the light blocking area BA. The first capping layer CAP1 flattens step differences of the color filter layer CFL.

The preliminary scattering layer PST is formed on the first capping layer CAP1. The preliminary scattering layer PST is entirely formed on the first to third light emitting areas EA1, EA2, and EA3 and the light blocking area BA. The preliminary scattering layer PST includes scattering particles and a photosensitive polymer in which the scattering particles are dispersed.

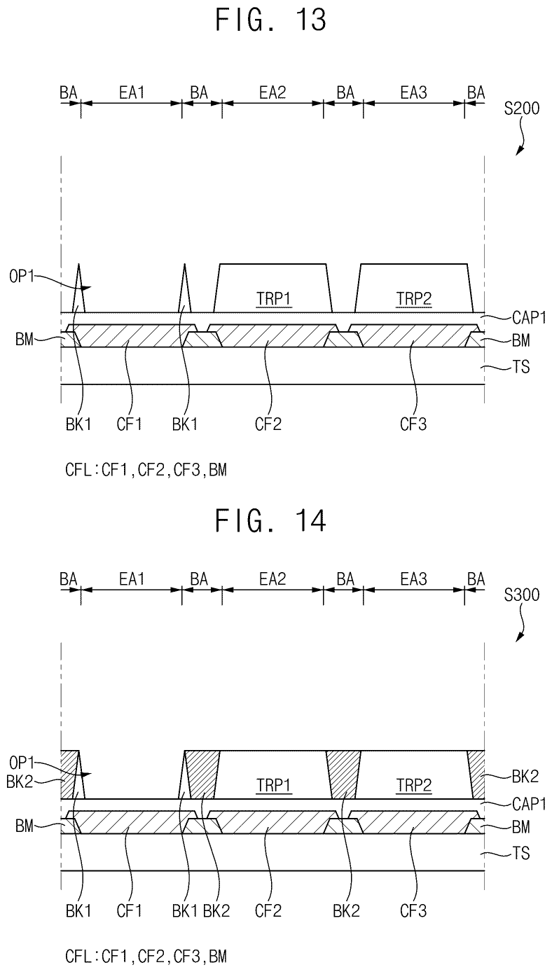

Referring to FIG. 13, in an embodiment, a first transmission pattern TRP1, a second transmission pattern TRP2, and a first bank BK1 are formed by patterning the preliminary scattering layer PST (S200). The first transmission pattern TRP1, the second transmission pattern TRP2, and the first bank BK1 are simultaneously formed.

The first bank BK1 is formed in the first light emitting area EA1 on the color filter layer CFL. The first bank BK1 overlaps an edge of the first color filter CF1, such as a portion adjacent to the light blocking pattern BM, in a plan view. A first opening OP1 is formed in the first bank BK1 that exposes a central portion of the first color filter CF1.

The first transmission pattern TRP1 is formed in the second light emitting area EA2 on the color filter layer CFL. The first transmission pattern TRP1 overlaps the second color filter CF2 in the second light emitting area EA2 in a plan view.

The second transmission pattern TRP2 is formed in the third light emitting area EA3 on the color filter layer CFL. The second transmission pattern TRP2 overlaps the third color filter CF3 in the third light emitting area EA3 in a plan view.

Referring to FIG. 14, in an embodiment, a second bank BK2 that contacts a side surface of the first bank BK1 is formed (S300).

The second bank BK2 is formed in the light blocking area BA on the first capping layer CAP1. For example, the second bank BK2 is formed between the first transmission pattern TRP1 and the second transmission pattern TRP2, between the first transmission pattern TRP1 and the first bank BK1, and between the second transmission pattern TRP2 and the first bank BK1.

The second bank BK2 contacts the side surface of the first bank BK1. In addition, the second bank BK2 contacts a side surface of the first transmission pattern TRP1 and a side surface of the second transmission pattern TRP2. The second bank BK2 is formed of a different material from the first bank BK1. For example, the second bank BK2 may include an organic material and/or an inorganic material that includes a black light blocking material.

When forming the second bank BK2 before the first bank BK1, the first transmission pattern TRP1, and the second transmission pattern TRP2, the second bank BK2 are formed by mixing a black pigment with other pigments, and the second bank BK2 is patterned through exposure and development. In this case, the second bank BK2 might not effectively block light, which can result in a color mixing phenomenon between adjacent sub-pixels.

In the method MM of manufacturing a display device according to an embodiment of FIGS. 1-3, after forming the first bank BK1, the first transmission pattern TRP1, and the second transmission pattern TRP2, the second bank BK2 is formed. For example, a space in which the second bank BK2 is accommodated is formed by the first bank BK1, the first transmission pattern TRP1, and the second transmission pattern TRP2. By forming the second bank BK2 in the space, the second bank BK2 can be formed to have a predetermined shape, even when the second bank BK2 includes carbon black. Since the second bank BK2 includes carbon black, the second bank BK2 can effectively block light as compared to a light blocking bank formed by mixing black pigment with other pigments. Accordingly, the color mixing phenomenon that occurs between the adjacent sub-pixels is reduced.

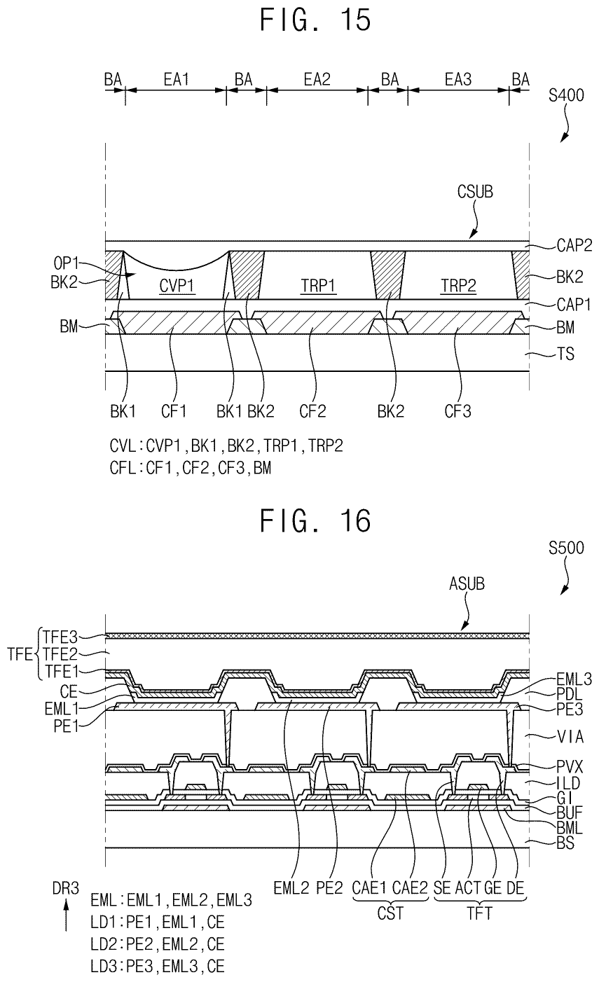

Referring to FIG. 15, in an embodiment, a first color conversion pattern CVP1 is formed inside the first opening OP1 defined by the first bank BK1 (S400).

The first color conversion pattern CVP1 is formed inside the first opening OP1 by an inkjet printing method. Accordingly, a thickness of the first color conversion pattern CVP1 increases from a central portion of the first color conversion pattern CVP1 toward the first bank BK1. The first color conversion pattern CVP1 overlaps the first color filter CF1 in the first light emitting area EA1 in a plan view.

A second capping layer CAP2 is formed on the color conversion layer CVL. The second capping layer CAP2 is entirely formed on the first to third light emitting areas EA1, EA2, and EA3 and the light blocking area BA. The second capping layer CAP2 flattens step differences of the color conversion layer CVL.

Accordingly, a color conversion substrate CSUB that includes the upper substrate TS, the color filter layer CFL, the first capping layer CAP1, the color conversion layer CVL, and the second capping layer CAP2 are formed.

Referring to FIGS. 16, 17, and 18, in an embodiment, the upper substrate TS and a lower substrate BS are bonded with a filling layer FIL therebetween (S500).

As illustrated in FIG. 16, in an embodiment, a light emitting layer EML is formed on the lower substrate BS. For example, an array substrate ASUB that includes the lower substrate BS, a lower pattern BML, a buffer layer BUF, a gate insulating layer GI, an inter-layer insulating layer ILD, a thin-film transistor TFT, a storage capacitor CST, a protective layer PVX, a via-insulating layer VIA, first to third pixel electrodes PE1, PE2, and PE3, a pixel defining layer PDL, the light emitting layer EML, a common electrode CE, and an encapsulation layer TFE, may be formed. The lower substrate BS corresponds to the substrate SUB that is illustrated in FIG. 2.

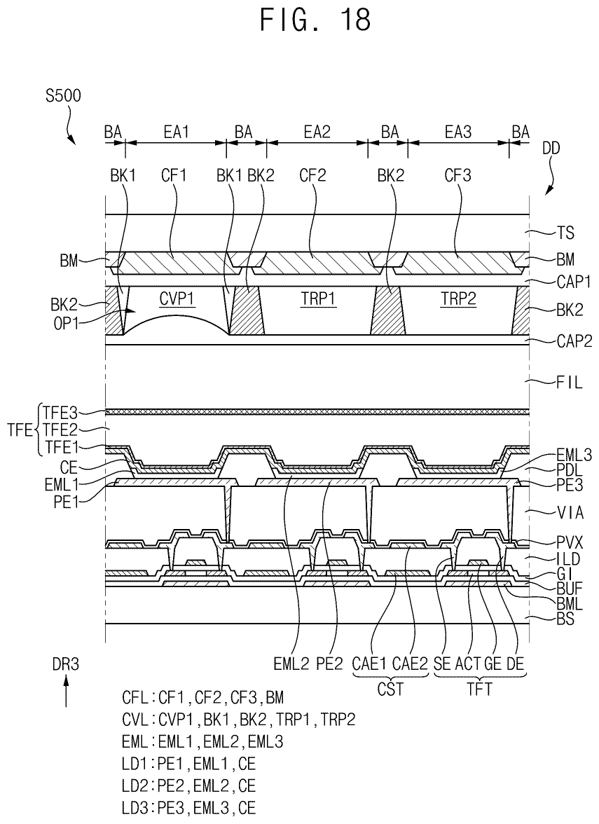

As illustrated in FIGS. 17 and 18, in an embodiment, the upper substrate TS and lower substrate BS are bonded with the filling layer FIL therebetween.

After aligning the lower substrate BS and the upper substrate TS such that the color conversion layer CVL faces the light emitting layer EML, the lower substrate BS is bonded with the upper substrate TS such that the light emitting layer EML overlaps each of the first to third light emitting areas EA1, EA2, and EA3. Accordingly, the first light emitting layer EML1 overlaps the first light emitting area EA1, the second light emitting layer EML2 overlaps the second light emitting area EA2, and the third light emitting layer EML3 overlaps the third light emitting area EA3.

A laser beam is irradiated to a sealing member SL to bond the lower substrate BS and the upper substrate TS. The sealing member SL includes an inorganic material. For example, the sealing member SL is a glass frit. When the sealing member SL is irradiated by a laser beam, the sealing member SL is melted and cured. Accordingly, the lower substrate BS and the upper substrate TS are bonded. After the lower substrate BS and the upper substrate TS are bonded, the filling layer FIL is cured by a method such as heat curing, UV curing, etc. Accordingly, the display device DD described above with reference to FIGS. 1, 2, and 3 can be formed.

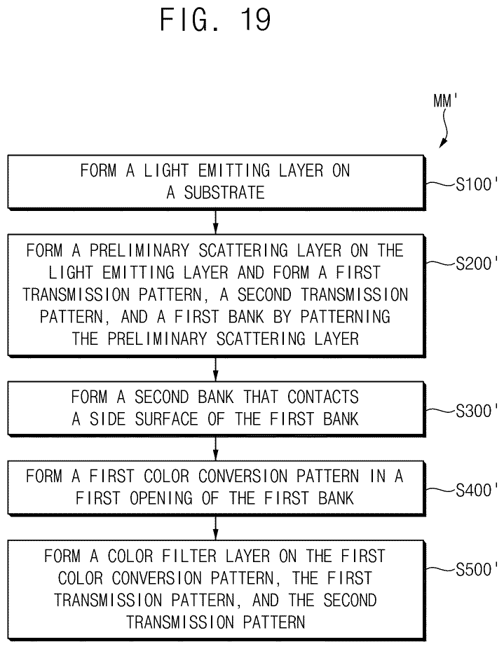

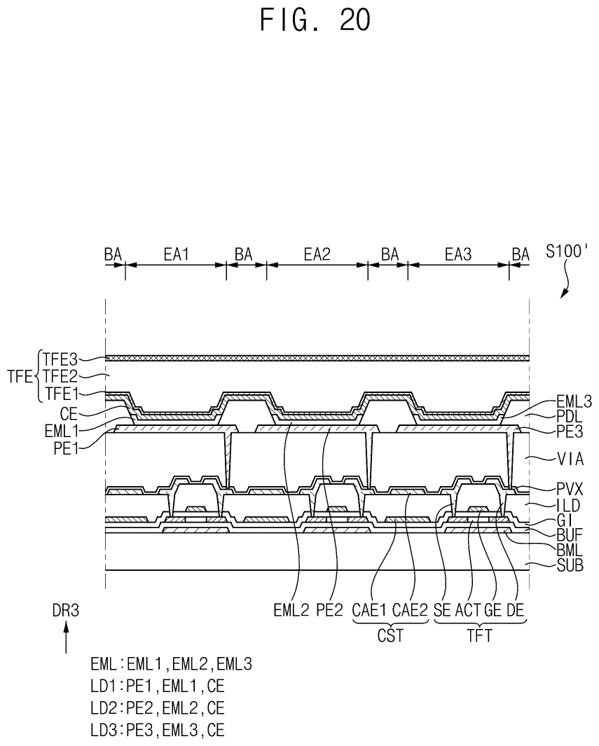

FIG. 19 is a flowchart of a method of manufacturing a display device according to an embodiment of FIG. 8. FIGS. 20, 21, 22, 23, 24, and 25 illustrate a method of manufacturing a display device of FIG. 19. A method MM′ of manufacturing a display device described below with reference to FIGS. 20 to 25 manufactures the display device DD3 described above with reference to FIG. 8, Accordingly, redundant descriptions of the display device DD3 described above with reference to FIG. 8 may be omitted or summarized.

A method of manufacturing the display device DD4 described above with reference to FIG. 9 is substantially the same as a method of manufacturing the display device DD3 described above with reference to FIG. 8, except that the first bank BK1 is further formed in the second light emitting area EA2 on the light emitting layer EML, and the second color conversion pattern CVP2 is formed inside the second opening OP2 of the first bank BK1 in the second light emitting area EA2. Accordingly, redundant descriptions of a method of manufacturing the display device DD4 described above with reference to FIG. 9 may be omitted or summarized.

Referring to FIG. 19, in an embodiment, a method MM′ of manufacturing a display device according to an embodiment of FIG. 8 includes forming a light emitting layer on a substrate (S100′), forming a preliminary scattering layer on the light emitting layer, and forming a first transmission pattern, a second transmission pattern, and a first bank by patterning the preliminary scattering layer (S200′), forming a second bank that contacts a side surface of the first bank (S300′), forming a first color conversion pattern in a first opening of the first bank (S400′), and forming a color filter layer on the first color conversion pattern, the first transmission pattern, and the second transmission pattern (S500′). Hereinafter, redundant descriptions of the method MM of manufacturing the display device described above with reference to FIGS. 11 to 18 may be omitted or summarized.

Referring to FIG. 20, in an embodiment, a light emitting layer EML is formed on a substrate SUB (S100′).

The substrate SUB includes first to third light emitting areas EA1, EA2, and EA3 and a light blocking area BA, and the light emitting layer EML includes first to third light emitting layers EML1, EML2, and EML3. The first light emitting layer EML1 overlaps the first light emitting area EA1, the second light emitting layer EML2 overlaps the second light emitting area EA2, and the third light emitting layer EML3 overlaps the third light emitting area EA3. An encapsulation layer TFE is formed on the light emitting layer EML.

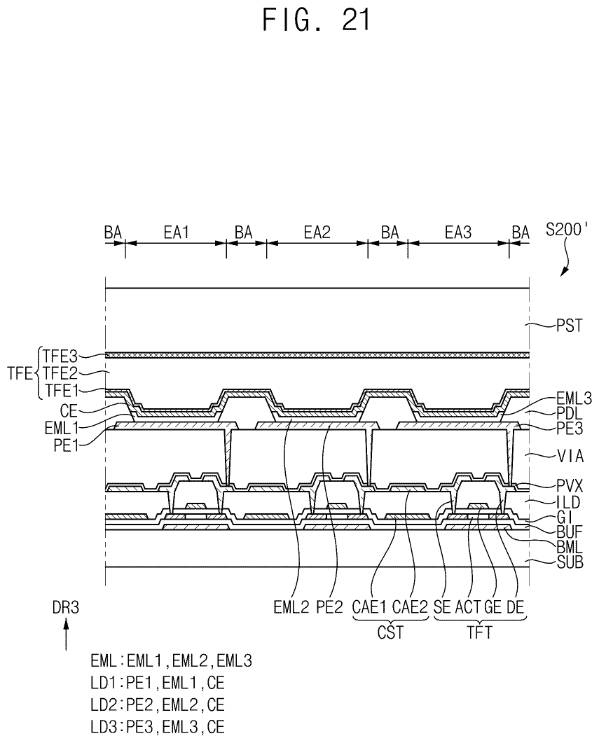

Referring to FIG. 21, in an embodiment, a preliminary scattering layer PST is formed on the light emitting layer EML (S200′). For example, the preliminary scattering layer PST is formed on the encapsulation layer TFE. The preliminary scattering layer PST is entirely formed on the first to third light emitting areas EA1, EA2, and EA3 and the light blocking area BA. The preliminary scattering layer PST includes scattering particles and a photosensitive polymer in which the scattering particles are dispersed.

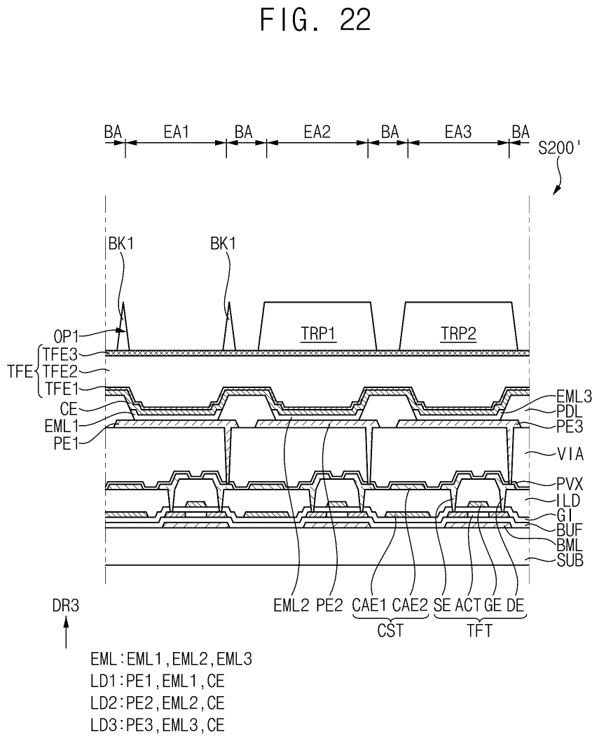

Referring to FIG. 22, in an embodiment, a first transmission pattern TRP1, a second transmission pattern TRP2, and a first bank BK1 are formed by patterning the preliminary scattering layer PST (S200′). The first transmission pattern TRP1, the second transmission pattern TRP2, and the first bank BK1 are simultaneously formed.

The first bank BK1 is formed in the first light emitting area EA1 on the light emitting layer EML. The first bank BK1 overlaps an edge of the first light emitting layer EML1, such as a portion adjacent to the pixel defining layer PDL, in a plan view. A first opening OP1 is formed in the first bank BK1 that overlaps a central portion of the first light emitting layer EML1 in a plan view.

The first transmission pattern TRP1 is formed in the second light emitting area EA2 on the light emitting layer EML. The first transmission pattern TRP1 overlaps the second light emitting layer EML2 in the second light emitting area EA2 in a plan view.

The second transmission pattern TRP2 is formed in the third light emitting area EA3 on the light emitting layer EML. The second transmission pattern TRP2 overlaps the third light emitting layer EML3 in the third light emitting area EA3 in a plan view.

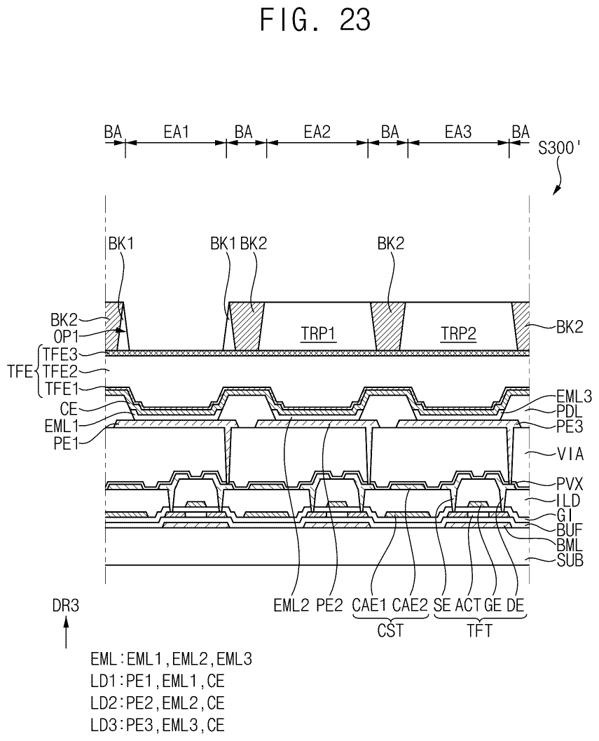

Referring to FIG. 23, in an embodiment, a second bank BK2 that contacts a side surface of the first bank BK1 is formed (S300′).

The second bank BK2 is formed in the light blocking area BA on the encapsulation layer TFE. For example, the second bank BK2 is formed between the first transmission pattern TRP1 and the second transmission pattern TRP2, between the first transmission pattern TRP1 and the first bank BK1, and between the second transmission pattern TRP2 and the first bank BK1. The second bank BK2 contacts the side surface of the first bank BK1. In addition, the second bank BK2 contacts a side surface of the first transmission pattern TRP1 and a side surface of the second transmission pattern TRP2. The second bank BK2 is formed of a different material from the first bank BK1. In an embodiment, the second bank BK2 includes carbon black. Accordingly, a color mixing phenomenon that can occur between adjacent sub-pixels is reduced.

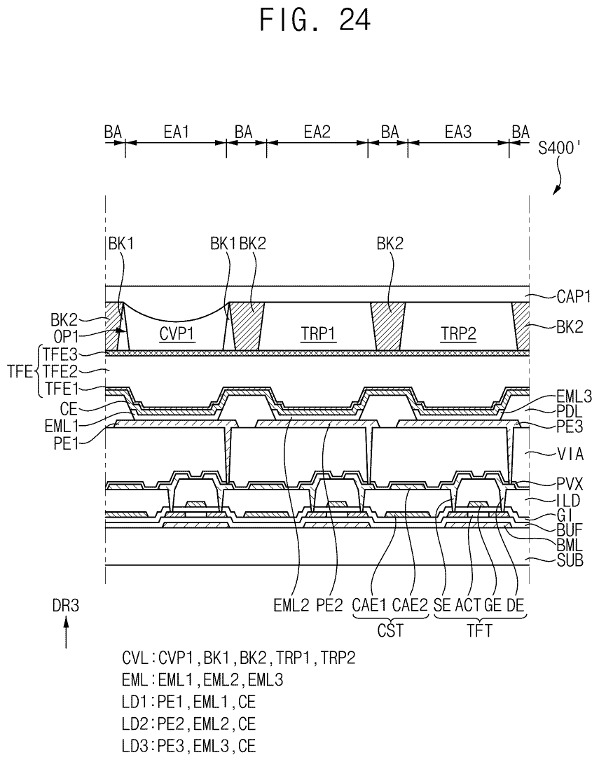

Referring to FIG. 24, in an embodiment, a first color conversion pattern CVP1 is formed inside the first opening OP1 of the first bank BK1 (S400′).

The first color conversion pattern CVP1 is formed inside the first opening OP1 by an inkjet printing method. The first color conversion pattern CVP1 overlaps the first light emitting layer EML1 in the first light emitting area EA1 in a plan view.

A first capping layer CAP1 is formed on the color conversion layer CVL. The first capping layer CAP1 is entirely formed on the first to third light emitting areas EA1, EA2, and EA3 and the light blocking area BA. The first capping layer CAP1 flattens step differences of the color conversion layer CVL.

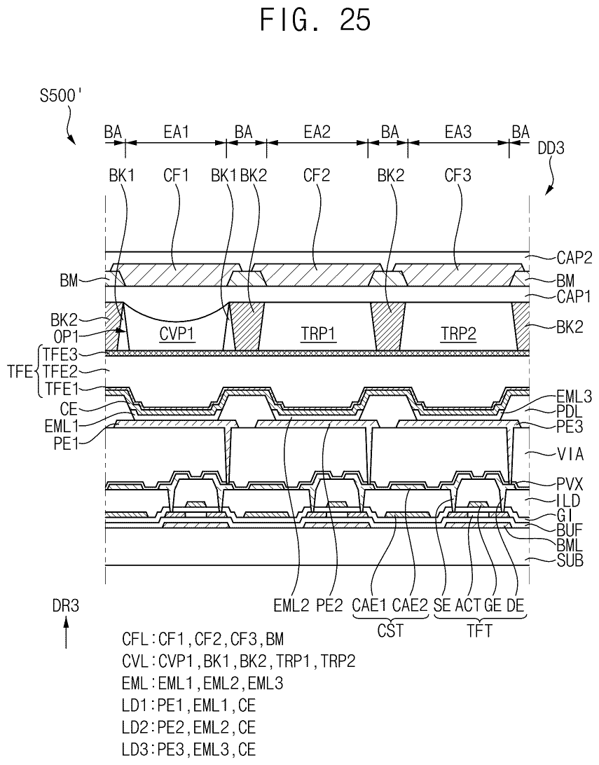

Referring to FIG. 25, in an embodiment, a color filter layer CFL is formed on the first color conversion pattern CVP1, the first transmission pattern TRP1, and the second transmission pattern TRP2 (S500′). For example, the color filter layer CFL may be formed on the first capping layer CAP1.

A light blocking pattern BM is formed that overlaps the light blocking area BA. The light blocking pattern BM includes a plurality of openings that partition the first to third light emitting areas EA1, EA2, and EA3.

After the light blocking pattern BM is formed, first to third color filters CF1, CF2, and CF3 are formed on the first capping layer CAP1. The first color filter CF1 overlaps the first light emitting area EA1, the second color filter CF2 overlaps the second light emitting area EA2, and the third color filter CF3 overlaps the third light emitting area EA3. In addition, the first color filter CF1 overlaps the first color conversion pattern CVP1 in a plan view, the second color filter CF2 overlaps the first transmission pattern TRP1 in a plan view, and the third color filter CF3 overlaps the second transmission pattern TRP2 in a plan view.

A second capping layer CAP2 is formed on the color filter layer CFL. The second capping layer CAP2 is entirely formed on the first to third light emitting areas EA1, EA2, and EA3 and the light blocking area BA. The second capping layer CAP2 flattens step differences of the color filter layer CFL. Accordingly, the display device DD3 described above with reference to FIG. 8 can be formed.

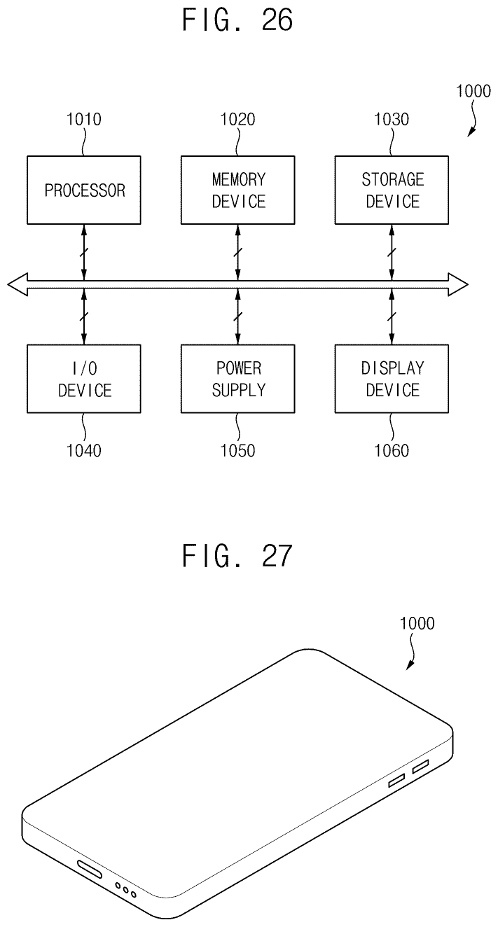

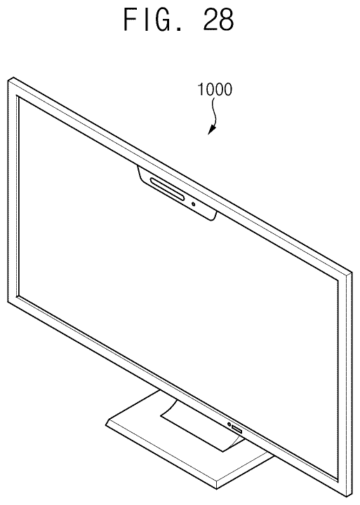

FIG. 26 is a block diagram of an electronic device according to an embodiment of the present disclosure. FIG. 27 illustrates an example in which the electronic device of FIG. 26 is implemented as a smart phone. FIG. 28 illustrates an example in which the electronic device of FIG. 26 is implemented as a computer monitor.

Referring to FIGS. 26, 27, and 28, an electronic device 1000 includes a processor 1010, a memory device 1020, a storage device 1030, an input/output (I/O) device 1040, a power supply 1050, and a display device 1060. The display device 1060 may correspond to any one of the display device DD of FIG. 2, the display device DD2 of FIG. 6, the display device DD3 of FIG. 8, or the display device DD4 of FIG. 9. In addition, the electronic device 1000 may further include a plurality of ports for communicating with a video card, a sound card, a memory card, a universal serial bus (USB) device, other systems, and the like.

In an embodiment, as illustrated in FIG. 27, the electronic device 1000 is implemented as a smart phone. In another embodiment, as illustrated in FIG. 28, the electronic device 1000 is implemented as a computer monitor. However, the electronic device 1000 is not limited thereto. For example, the electronic device 1000 may be implemented as a smart pad, a smart watch, a tablet PC, a car navigation system, a laptop, a head mounted display (“HMD”) device, and the like.

The processor 1010 can perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 is coupled to an extended bus such as a peripheral component interconnection (“PCI”) bus.

The memory device 1020 can store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 includes the display device 1060.

The power supply 1050 can provide power for operations of the electronic device 1000. For example, the power supply 1050 provides power to the display device 1060. The display device 1060 can be connected to other components through buses or other communication links.

Embodiments of the present disclosure can be incorporated into various display devices. For example, embodiments of the present disclosure can be incorporated into various display devices, such as display devices for vehicles, ships and aircraft, portable communication devices, display devices for exhibition or information transmission, medical display devices, and the like.

The foregoing is illustrative of embodiments of the present disclosure, and is not to be construed as limiting thereof. Although a few embodiments have been described with reference to the figures, those skilled in the art will readily appreciate that many variations and modifications may be made therein without departing from the spirit and scope of embodiments of the present disclosure as defined in the appended claims.

What is claimed is:

1. A display device, comprising:
a substrate that includes first to third light emitting areas and a light blocking area that surrounds the first to third light emitting areas;
a light emitting layer that includes first to third light emitting layers disposed on the substrate in the first to third light emitting areas, respectively; and
a color conversion layer, wherein the color conversion layer includes:
a first bank disposed in the first light emitting area on the light emitting layer, overlaps an edge of the first light emitting layer in a plan view, and includes a first opening that exposes a central portion of the first light emitting layer;
a second bank disposed in the light blocking area on the light emitting layer, contacts a side surface of the first bank, and includes a material different from the first bank; and
a first color conversion pattern disposed inside the first opening of the first light emitting area.

2. The display device of claim 1, wherein
the first bank includes a scattering particle, and
the second bank includes carbon black.

3. The display device of claim 1, wherein the color conversion layer further includes:
a first transmission pattern disposed in the second light emitting area on the light emitting layer and that is surrounded by the second bank; and
a second transmission pattern disposed in the third light emitting area on the light emitting layer and that is surrounded by the second bank.

4. The display device of claim 3, wherein
the first conversion pattern converts light emitted from the light emitting layer into light of a first color, and
each of the first transmission pattern and the second transmission pattern transmits the light emitted from the light emitting layer.

5. The display device of claim 4, wherein
the first color is red, and
each of the first to third light emitting layers emits green light and blue light.

6. The display device of claim 3, wherein the first bank includes a same material as the first transmission pattern and the second transmission pattern.

7. The display device of claim 1, wherein
the first bank is further disposed in the second light emitting area on the light emitting layer, overlaps an edge of the second light emitting layer in a plan view, and includes a second opening that exposes a central portion of the second light emitting layer, and
the color conversion layer further includes a second color conversion pattern disposed inside the second opening in the second light emitting area, and a transmission pattern disposed in the third light emitting area on the light emitting layer and that is surrounded by the second bank.

8. The display device of claim 7, wherein
the first color conversion pattern converts light emitted from the light emitting layer into light of a first color,
the second color conversion pattern converts the light emitted from the light emitting layer into light of a second color, and
the transmission pattern transmits the light emitted from the light emitting layer.

9. The display device of claim 8, wherein
the first color is red,
the second color is green, and
each of the first to third light emitting layers emits only blue light, or emits green light and blue light.

10. The display device of claim 1, wherein the second bank includes a liquid-repellent material.

11. The display device of claim 1, further comprising:
a color filter layer disposed on the color conversion layer and that includes first to third color filters that overlap the first to third light emitting areas, respectively.

12. A method of manufacturing a display device, the method comprising:
forming a color filter layer on a first substrate that includes first to third light emitting areas and a light blocking area that surrounds the first to third light emitting areas, wherein the color filter layer includes first to third color filters that overlap the first to third light emitting areas, respectively;
forming a preliminary layer on the color filter layer;
patterning the preliminary layer and forming a first bank that overlaps an edge of the first color filter in a plan view and includes a first opening that exposes a central portion of the first color filter in the first light emitting area;
forming a second bank that overlaps the light blocking area, contacts a side surface of the first bank, and includes a material different from the first bank;
forming a first color conversion pattern that overlaps the first light emitting area and is disposed inside the first opening; and
forming a light emitting layer on a second substrate and bonding the first substrate and the second substrate such that the light emitting layer overlaps each of the first to third light emitting areas.

13. The method of claim 12, wherein
the first bank includes a scattering particle, and
the second bank includes carbon black.

14. The method of claim 12, further comprising:
patterning the preliminary layer and forming a first transmission pattern that overlaps the second color filter in the second light emitting area in a plan view, and a forming second transmission pattern that overlaps the third color filter in the third light emitting area in a plan view,
wherein the first transmission pattern and the second transmission pattern are simultaneously formed with the first bank.

15. The method of claim 12, further comprising:
patterning the preliminary layer and forming a transmission pattern that overlaps the third color filter in the third light emitting area in a plan view,
wherein the first bank further overlaps an edge of the second color filter in a plan view and further includes a second opening that exposes a central portion of the second color filter in the second light emitting area, and
the transmission pattern is simultaneously formed with the first bank.

16. The method of claim 15, further comprising:
forming a second color conversion pattern that overlaps the second light emitting area and is disposed inside the second opening.

17. A method of manufacturing a display device, the method comprising:
forming a light emitting layer on a substrate that includes first to third light emitting areas and a light blocking area that surrounds the first to third light emitting areas, wherein the light emitting layer includes first to third light emitting layers that overlap the first to third light emitting areas, respectively;
forming a preliminary layer on the light emitting layer;
patterning the preliminary layer and forming a first bank that overlaps an edge of the first light emitting layer in a plan view and includes a first opening that exposes a central portion of the first light emitting layer in the first light emitting area;
forming a second bank that overlaps the light blocking area, contacts a side surface of the first bank, and includes a material different from the first bank; and
forming a first color conversion pattern that overlaps the first light emitting area and is disposed inside the first opening.

18. The method of claim 17, further comprising:
patterning the preliminary layer and forming a first transmission pattern that overlaps the second light emitting layer in the second light emitting area in a plan view and a second transmission pattern that overlaps the third light emitting layer in the third light emitting area in a plan view,
wherein the first transmission pattern and the second transmission pattern are simultaneously formed with the first bank.

19. The method of claim 17, further comprising:
patterning the preliminary layer and forming a transmission pattern that overlaps with the third light emitting layer in the third light emitting area in a plan view, wherein the first bank further overlaps an edge of the second light emitting layer in a plan view and further includes a second opening that exposes a central portion of the second light emitting layer in the second light emitting area, and
the transmission pattern is simultaneously formed with the first bank.

20. The method of claim 19, further comprising:
forming a second color conversion pattern that overlaps the second light emitting area and is disposed inside the second opening.

21. An electronic device, comprising:
a display device; and
a power supply configured to provide power to the display device,
wherein the display device comprises:
a substrate that includes first to third light emitting areas and a light blocking area that surrounds the first to third light emitting areas;
a light emitting layer that includes first to third light emitting layers disposed on the substrate in the first to third light emitting areas, respectively; and
a color conversion layer, wherein the color conversion layer includes:
a first bank disposed in the first light emitting area on the light emitting layer, overlaps an edge of the first light emitting layer in a plan view, and includes a first opening that exposes a central portion of the first light emitting layer;
a second bank disposed in the light blocking area on the light emitting layer, contacts a side surface of the first bank, and includes a material different from the first bank; and
a first color conversion pattern disposed inside the first opening of the first light emitting area.
